(19) United States
(12) Patent Application Publication
(10) Pub. No.: US 2022/0406786 A1
(43) Pub. Date: Dec. 22, 2022

(54) SEMICONDUCTOR DEVICES HAVING DUMMY GATE STRUCTURES

(71) Applicant: Samsung Electronics Co., Ltd., Suwon-si (KR)

(72) Inventor: Jongin Kang, Hwaseong-si (KR)

(21) Appl. No.: 17/568,262

(22) Filed: Jan. 4, 2022

(30) Foreign Application Priority Data
Jun. 17, 2021 (KR) 10-2021-0078683

(51) Int. Cl. H01L 27/108

(52) U.S. Cl. CPC H01L 27/10823; H01L 27/10814; H01L 27/10876; H01L 27/10885

(57) ABSTRACT

A semiconductor device includes a substrate including a cell area and an interface area surrounding the cell area, the substrate including a device isolation layer defining an active region in the cell area and including an area isolation layer in the interface area, a gate structure extending in the cell area in a first horizontal direction, the gate structure being buried in the substrate and intersecting the active region, a bit line structure intersecting the gate structure and extending in a second horizontal direction intersecting the first horizontal direction, and dummy gate structures extending in the interface area in the first horizontal direction and being spaced apart from one another in the second horizontal direction. The dummy gate structures are buried in the area isolation layer and being spaced apart from the gate structure in the second horizontal direction.

### CROSS-REFERENCE TO THE RELATED APPLICATION

This application claims priority from Korean Patent Application No. 10-2021-0078683, filed on Jun. 17, 2021, in the Korean Intellectual Property Office, the disclosure of which is incorporated herein by reference in its entirety.

### BACKGROUND

### 1. Field

The present disclosure relates to semiconductor devices.

### 2. Description of the Related Art

In accordance with demand for high integration and miniaturization of semiconductor devices, semiconductor devices are being scaled down in size. Accordingly, a semiconductor memory device used in an electronic appliance may require high integration and, as such, design rules for constituent elements of the semiconductor memory device may be reduced. Reducing the size of a semiconductor device, however, may risk degrading the reliability of the semiconductor device.

### SUMMARY

The example embodiments of the disclosure provide a semiconductor device having a dummy gate structure.

A semiconductor device according to example embodiments of the disclosure may include a substrate including a cell area and an interface area surrounding the cell area, the substrate including a device isolation layer defining an active region in the cell area and including an area isolation layer in the interface area, a gate structure extending in the cell area in a first horizontal direction, the gate structure being buried in the substrate and intersecting the active region, a bit line structure intersecting the gate structure and extending in a second horizontal direction intersecting the first horizontal direction, and dummy gate structures extending in the interface area in the first horizontal direction and being spaced apart from one another in the second horizontal direction. The dummy gate structures may be buried in the area isolation layer and may be spaced apart from the gate structure in the second horizontal direction.

A semiconductor device according to example embodiments of the disclosure may include a substrate including a cell area and an interface area bordering the cell area. The semiconductor device includes a device isolation layer in the cell area and defining an active region of the substrate in the cell area. Moreover, the semiconductor device includes an area isolation layer in the interface area, gate structures extending in the cell area in a first horizontal direction, the gate structures extending below a level of a top surface of the substrate and intersecting the active region, a bit line structure intersecting the gate structures and extending in a second horizontal direction intersecting the first horizontal direction, and dummy gate structures extending in the interface area in the first horizontal direction and being spaced apart from one another by a first distance in the second horizontal direction. The dummy gate structures may be spaced apart from the gate structures in the second horizontal direction, and a minimum distance between the dummy gate structures and the gate structures may be greater than the first distance.

A semiconductor device according to example embodiments of the disclosure may include a substrate including a cell area and an interface area surrounding the cell area, the substrate including a device isolation layer defining an active region in the cell area and including an area isolation layer in the interface area, a gate structure extending in the cell area in a first horizontal direction, the gate structure being buried in the substrate and intersecting the active region, a bit line structure intersecting the gate structure and extending in a second horizontal direction intersecting the first horizontal direction, a bit line material layer on the area isolation layer and being spaced apart from the bit line structure in the first horizontal direction, edge spacers in the interface area, the edge spacers contacting side surfaces of the bit line structure and the bit line material layer, a direct contact under the bit line structure in the cell area, the direct contact contacting the active region, a buried contact at a side surface of the gate structure, the buried contact contacting the active region, and dummy gate structures extending in the interface area in the first horizontal direction and being spaced apart from one another in the second horizontal direction. The dummy gate structures may be buried in the area isolation layer and may be spaced apart from the gate structure in the second horizontal direction.

### BRIEF DESCRIPTION OF THE DRAWINGS

FIG. 1 is a plan view of a semiconductor device according to an example embodiment of the inventive concepts.

FIG. 2 is a vertical cross-sectional view of the semiconductor device taken along line I-I′ shown in FIG. 1.

FIG. 3 includes vertical cross-sectional views of the semiconductor device taken along lines II-II′ and III-III′ shown in FIG. 1.

FIGS. 4 to 33 are plan views and vertical cross-sectional views illustrating, in process order, a method of manufacturing a semiconductor device according to an example embodiment of the inventive concepts.

FIG. 34 is a vertical cross-sectional view of a semiconductor device according to an example embodiment of the inventive concepts.

FIGS. 35 to 38 are plan views and vertical cross-sectional views of a semiconductor device according to an example embodiment of the inventive concepts.

FIGS. 39 to 41 are plan views and vertical cross-sectional views of a semiconductor device according to an example embodiment of the inventive concepts.

FIGS. 42 to 44 are plan views and vertical cross-sectional views of semiconductor devices according to example embodiments of the inventive concepts.

### DETAILED DESCRIPTION

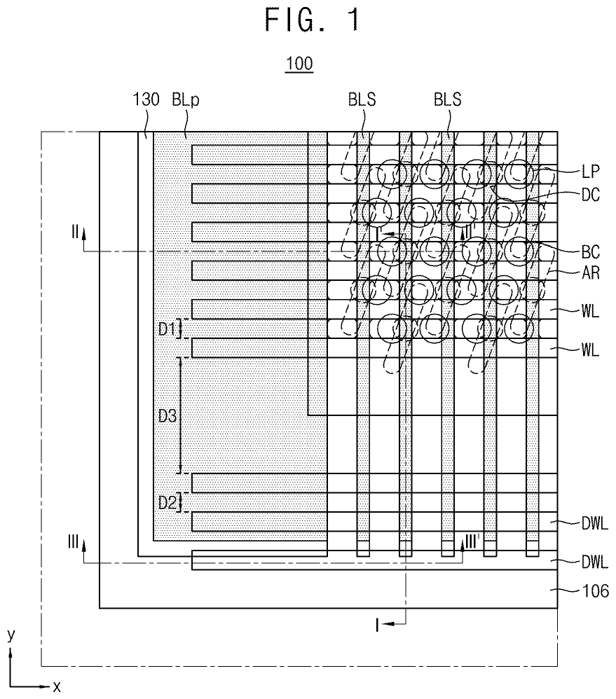

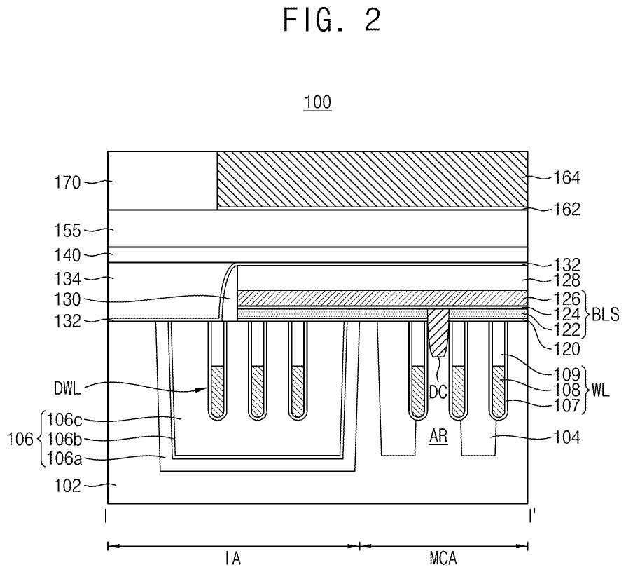

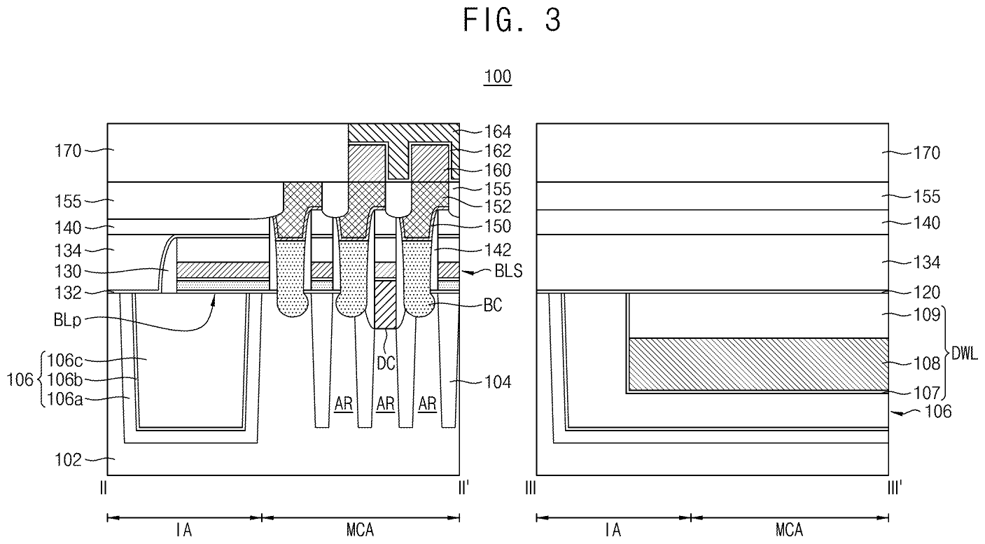

FIG. 1 is a plan view of a semiconductor device according to an example embodiment of the inventive concepts. FIG. 2 is a vertical cross-sectional view of the semiconductor device taken along line I-I′ shown in FIG. 1. FIG. 3 includes vertical cross-sectional views of the semiconductor device taken along lines II-II′ and III-III′ shown in FIG. 1.

Referring to FIGS. 1 to 3, a semiconductor device 100 may include a substrate 102, a gate structure WL, a dummy gate structure DWL, a bit line structure BLS, an edge spacer 130, an insulating spacer 142, a buried contact BC, a conductive pattern 152, a lower electrode 160, a capacitor dielectric layer 162, and an upper electrode 164.

The substrate 102 may include a cell area MCA and an interface area IA. The cell area MCA may be an area in which a memory cell of a DRAM device is disposed, and the interface area IA may be an area between a peripheral circuit area (not shown), in which a row decoder, a sense amplifier, etc. are disposed, and the cell area MCA. For example, the interface area IA may border (e.g., surround and/or be adjacent) the cell area MCA. The substrate 102 may include a semiconductor material. For example, the substrate 102 may be a silicon substrate, a germanium substrate, a silicon germanium substrate, or a silicon-on-insulator (SOI) substrate.

The substrate 102 may include an active region AR, a device isolation layer 104, and an area isolation layer 106. The device isolation layer 104 may be an insulating layer extending downwards from a level of a top surface of the substrate 102, and may define active regions AR in the cell area MCA. For example, the active regions AR may correspond to a portion of the top surface of the substrate 102 surrounded by the device isolation layer 104. When viewed in a plan view, the active regions AR may have a bar shape having a shorter axis and a longer axis, and may be spaced apart from one another. Unlike the gate structures WL, the dummy gate structures DWL are electrically isolated (by the area isolation layer 106) from the substrate 102. None of the dummy gate structures DWL is in contact with any of the active regions AR (or any other region) of the substrate 102. In some embodiments, the area isolation layer 106 may extend continuously to contact respective lower ends of each of a plurality of dummy gate structures DWL, as shown in the cross-sectional view of FIG. 2.

The area isolation layer 106 may define the interface area IA. For example, when viewed in a cross-sectional view, an area, in which the area isolation layer 106 is disposed, and an area opposite to the cell area MCA with reference to the area isolation layer 106 may be referred to as the interface area IA. When viewed in a plan view, the area isolation layer 106 may surround the cell area MCA.

The area isolation layer 106 may be an insulating layer extending downwards from the level of the top surface of the substrate 102. When viewed in a cross-sectional view, the horizontal width of the area isolation layer 106 may be greater than the horizontal width of the device isolation layer 104. The area isolation layer 106 may include a first area isolation layer 106a, a second area isolation layer 106b and a third area isolation layer 106c which are sequentially stacked. The first area isolation layer 106a and the third isolation layer 106c may include silicon oxide, and the second area isolation layer 106b may include silicon nitride. The area isolation layer 106 may electrically insulate the active region AR from a portion of the substrate 102 in the interface area IA.

When viewed in a plan view, gate structures WL may extend in the cell area MCA in an x-direction while being spaced apart from one another in a y-direction. In an embodiment, the gate structures WL may further extend to the interface area IA. In the specification, the x-direction and the y-direction may be referred to as a first horizontal direction and a second horizontal direction, respectively. In addition, the gate structures WL may intersect the active region AR. For example, two gate structures WL may intersect one active region AR. When viewed in a cross-sectional view, the gate structures WL may be buried in the substrate 102 (e.g., may extend vertically below a level of the top surface of the substrate 102), and, for example, may be disposed within a trench formed in the substrate 102. The semiconductor device 100 may further include a gate dielectric layer 107, a gate conductive layer 108 and a gate capping layer 109 which are disposed within the trench. The gate dielectric layer 107 may be conformally formed at an inner wall of the trench. The gate conductive layer 108 may be disposed at a lower portion of the trench, and the gate capping layer 109 may be disposed at an upper portion of the gate structure WL. A top surface of the gate capping layer 109 may be coplanar with top surfaces of the device isolation layer 104 and the area isolation layer 106.

When viewed in a plan view, dummy gate structures DWL may be disposed in the interface area IA while being spaced apart from the gate structures WL in the y-direction. The dummy gate structures DWL may extend in the x-direction while being spaced apart from one another in the y-direction. When viewed in a cross-sectional view, the dummy gate structures DWL may be disposed in the area isolation layer 106. The dummy gate structures DWL may have a configuration identical or similar to that of the gate structures WL. For example, the dummy gate structures DWL may include a gate dielectric layer 107, a gate conductive layer 108, and a gate capping layer 109.

The horizontal width of the dummy gate structure DWL in the y-direction may be equal to the horizontal width of the gate structure WL in the y-direction. When viewed in a plan view, the gate structures WL may be spaced apart from one another in the y-direction by a uniform distance, and the dummy gate structures DWL may be spaced apart from one another in the y-direction by a uniform distance. For example, the gate structures WL may be spaced apart from one another in the y-direction by a first distance D1, and the dummy gate structures DWL may be spaced apart from one another in the y-direction by a second distance D2. The first distance D1 and the second distance D2 may be substantially equal. However, the distance between a gate structure WL and a dummy gate structure DWL that are adjacent to each other (e.g., that have no other gate structure WL or dummy gate structure DWL therebetween), that is, a third distance D3, which is the minimum distance between the gate structures WL and the dummy gate structures DWL, may be greater than the first distance D1 and the second distance D2. For example, the third distance D3 may be two times or more the first distance D1 and the second distance D2.

The semiconductor device 100 may further include a buffer layer 120 on (e.g., covering) the top surfaces of the device isolation layer 104 and the area isolation layer 106, and top surfaces of the gate structure WL and the dummy gate structure DWL. The buffer layer 120 may include silicon nitride.

When viewed in a plan view, bit line structures BLS may extend in the y-direction while being spaced apart from one another in the x-direction. In some embodiments, a bit line structure BLS may extend continuously from the memory cell area MCA to the interface area IA. For example, the bit line structure BLS may extend continuously from a first portion thereof that vertically overlaps a first of the gate structures WL to a second portion thereof that vertically overlaps a first of the dummy gate structures DWL. Moreover, at least one of the dummy gate structures DWL may not be vertically overlapped by the bit line structure BLS, as shown in FIG. 2. The bit line structure BLS may have a bar shape extending in the y-direction. When viewed in a cross-sectional view, the bit line structure BLS may include a first conductive layer 122, a second conductive layer 124 and a third conductive layer 126 which are sequentially stacked on the buffer layer 120.

The semiconductor device 100 may further include a first capping layer 128 and an insulating liner 132 which are sequentially stacked on the bit line structure BLS. The first conductive layer 122, the second conductive layer 124, the third conductive layer 126, and the first capping layer 128 may extend in the y-direction, and may have substantially the same width when viewed in a cross-sectional view. The insulating liner 132 may be on (e.g., may cover) the first capping layer 128 in the cell area MCA, and may extend to the interface area IA. For example, the insulating liner 132 may be on (e.g., may cover) the top surfaces of the substrate 102 and the device isolation layer 106.

The first conductive layer 122 may include polysilicon, and each of the second conductive layer 124 and the third conductive layer 126 may include titanium nitride (TiN), titanium silicon nitride (TiSiN), tungsten (W), tungsten silicide, or a combination thereof. The first capping layer 128 and the insulating liner 132 may include silicon oxide, silicon nitride, silicon oxynitride, or a combination thereof In an embodiment, the first capping layer 128 and the insulating liner 132 may both include silicon nitride.

The buffer layer 120, the first conductive layer 122, the second conductive layer 124, the third conductive layer 126 and the first capping layer 128 may further extend to the interface area IA. For example, ends of the buffer layer 120, the first conductive layer 122, the second conductive layer 124, the third conductive layer 126 and the first capping layer 128 may be disposed on the area isolation layer 106.

The semiconductor device 100 may further include a direct contact DC disposed under the bit line structure BLS, at a portion thereof where the bit line structure BLS contacts the active region AR. For example, the direct contact DC may be in (e.g., may fill) a recess formed at the top surface of the substrate 102. When viewed in a plan view, the direct contact DC may contact a central portion of the active region AR. A top surface of the direct contact DC may be disposed at the same level as a top surface of the first conductive layer 122. The bit line structure BLS may be disposed on direct contacts DC. The direct contact DC may electrically connect the active region AR to the bit line structure BLS. For example, the direct contact DC may extend through the first conductive layer 122 of the bit line structure BLS, and may be electrically connected to the second conductive layer 124 and the third conductive layer 126. The direct contact DC may include polysilicon. The interface area IA may be free (i.e., devoid) of any contact that contacts the substrate 102, and thus may be free of any direct contacts DC.

The semiconductor device 100 may further include the edge spacer 130. The edge spacer 130 may be on (e.g., may cover) the ends of the buffer layer 120, the first conductive layer 122, the second conductive layer 124, the third conductive layer 126 and the first capping layer 128. The edge spacer 130 may be disposed in the interface area IA, and, for example, may be disposed on the area isolation layer 106. The edge spacer 130 may be covered by the insulating liner 132, which extends from the cell area MCA. For example, the insulating liner 132 may extend between the interlayer insulating layer 134 and a curved sidewall of the edge spacer 130. The edge spacer 130 may include silicon oxide.

The semiconductor device 100 may further include a bit line material layer BLp, which is disposed on the device isolation layer 106. The bit line material layer BLp may include a configuration identical or similar to that of the bit line structure BLS. For example, the bit line material layer BLp may include a first conductive layer 122, a second conductive layer 124, and a third conductive layer 126. An end surface of the bit line material layer BLp may be disposed on the area isolation layer 106, and may contact the edge spacer 130.

The semiconductor device 100 may further include an interlayer insulating layer 134 and a second capping layer 140. The interlayer insulating layer 134 may be disposed on the insulating liner 132 in the interface area IA. In addition, the interlayer insulating layer 134 may be disposed at a side surface of the edge spacer 130. A top surface of the interlayer insulating layer 134 may be coplanar with a top surface of the insulating liner 132. The interlayer insulating layer 134 may include silicon oxide, silicon nitride, silicon oxynitride, or a combination thereof.

The second capping layer 140 may be disposed in the cell area MCA and the interface area IA. The second capping layer 140 may be on (e.g., may cover the top surface of) the insulating liner 132 in the cell area MCA while being on (e.g., covering the top surface of) the interlayer insulating layer 134 in the interface area IA.

Insulating spacers 142 may be disposed at opposite side surfaces of the bit line structures BLS, respectively, and may extend in the y-direction. The insulating spacers 142 may also be on (e.g., may cover) side surfaces of the first capping layer 128, the insulating liner 132 and the second capping layer 140. A part of the insulating spacers 142 may extend into the recess of the substrate 102, and may be on (e.g., may cover) a side surface of the direct contact DC. The insulating spacers 142 may be constituted by a single layer or multiple layers.

The buried contact BC may be disposed among the bit line structures BLS. A top surface of the buried contact BC may be disposed at a lower level than a top surface of the second capping layer 140, and a lower portion of the buried contact BC may extend into the substrate 102. For example, a lower end of the buried contact BC may be disposed at a lower level than the top surface of the substrate 102, and may contact the active region AR. The semiconductor device 100 may further include fence insulating layers (not shown) disposed alternately with the buried contact BC in the y-direction when viewed in a plan view. The fence insulating layers may overlap with gate electrodes. The buried contact BC may include polysilicon.

When viewed in a plan view, a landing pad LP may be disposed to overlap with the buried contact BC. When viewed in a cross-sectional view, a barrier pattern 150 and a conductive pattern 152 may be disposed on the buried contact BC. A top surface of the conductive pattern 152 may correspond to the landing pad LP, which is shown in a plan view. The barrier pattern 150 may be conformally formed along top surfaces of the bit line structure BLS and the buried contact BC, and the conductive pattern 152 may be disposed on the barrier pattern 150. For example, a lower surface of the conductive pattern 152 may be disposed at a lower level than the top surface of the second capping layer 140, and may correspond to (e.g., may be electrically connected to) the buried contact BC. A top surface of the conductive pattern 152 may be disposed at a higher level than the second capping layer 140. The conductive pattern 152 may be electrically connected to the active region AR via the buried contact BC. As the interface area IA may be free of any contact that contacts the substrate 102, the interface area IA may be free of any buried contacts BC.

The semiconductor device 100 may further include an insulating structure 155 disposed among landing pads LP. The insulating structure 155 may electrically insulate conductive patterns 152 from one another. A top surface of insulating structures 155 may be coplanar with the top surface of the conductive pattern 152. In an embodiment, the conductive pattern 152 may include tungsten, and the insulating structure 155 may include silicon oxide.

A capacitor structure of the semiconductor device 100 may be disposed on the landing pad LP. The capacitor structure may be constituted by the lower electrode 160, the capacitor dielectric layer 162, and the upper electrode 164. Each of lower electrodes 160 may be disposed to contact the landing pad LP corresponding thereto, and the capacitor dielectric layer 162 may be conformally disposed along the insulating structure 155 and the lower electrode 160. The upper electrode 164 may be disposed on the capacitor dielectric layer 162.

The semiconductor device 100 may further include an upper insulating layer 170 disposed on the insulating structure 155. The upper insulating layer 170 may be disposed in the interface area IA, and may contact the upper electrode 164. For example, a lower surface of the upper insulating layer 170 may contact the conductive pattern 152 and the insulating structure 155, and a top surface of the upper insulating layer 170 may be coplanar with a top surface of the upper electrode 164.

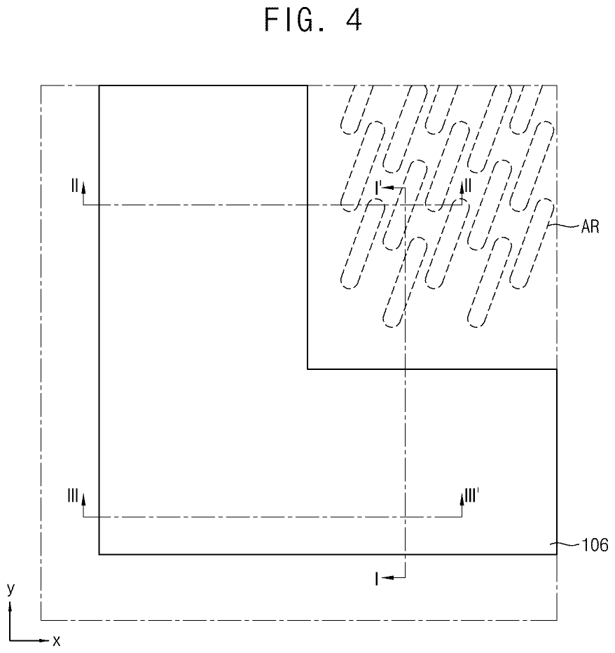

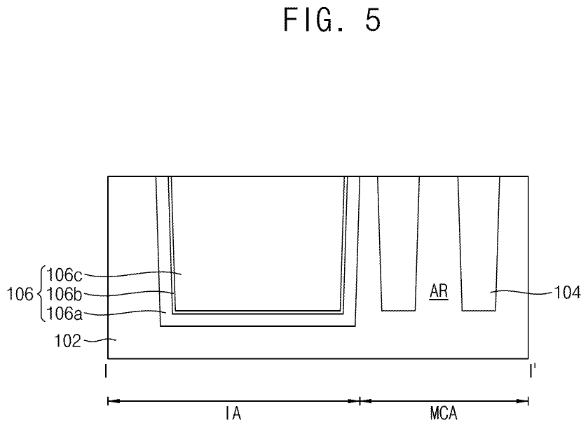

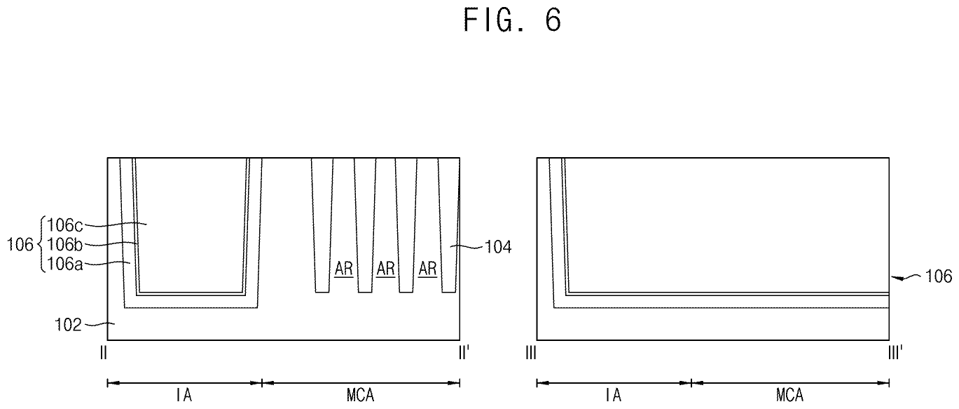

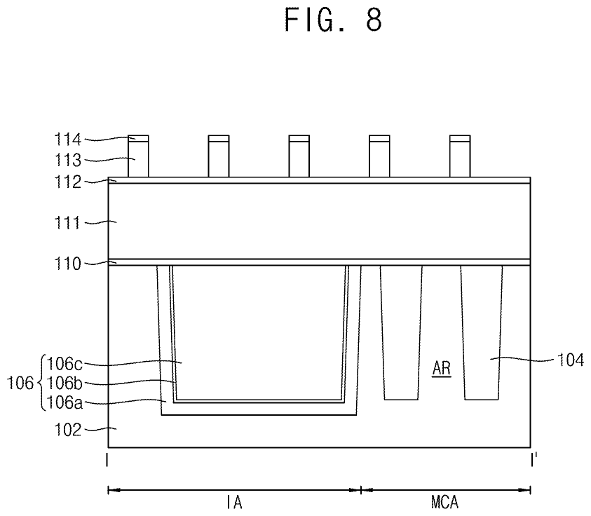

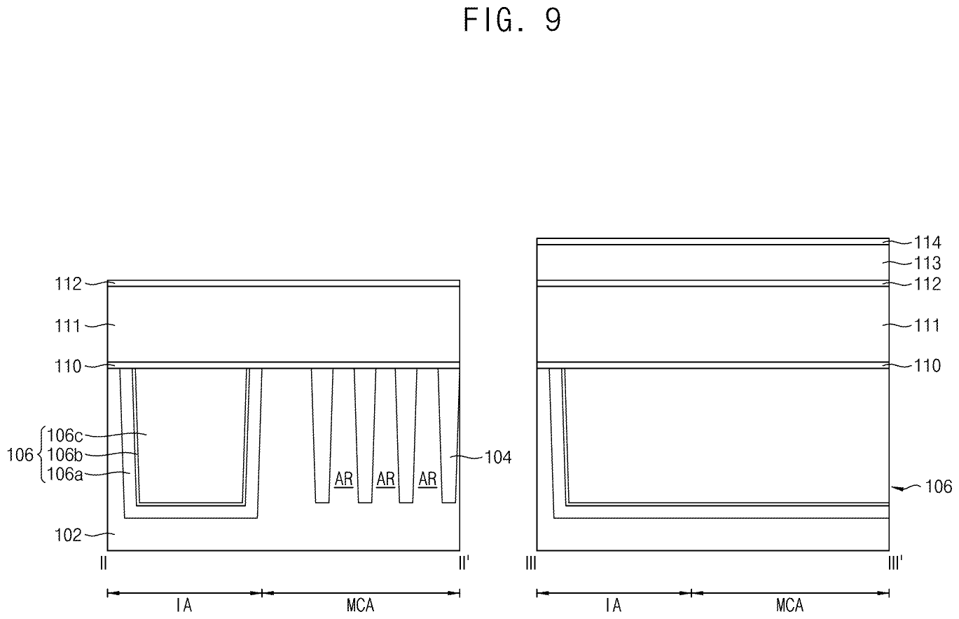

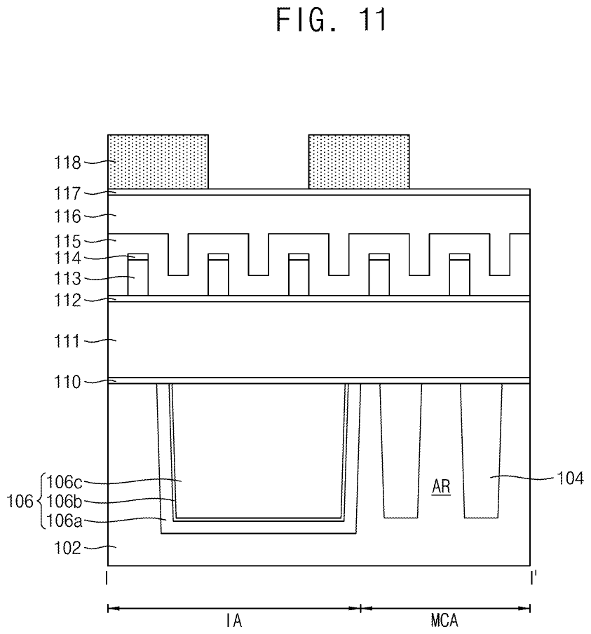

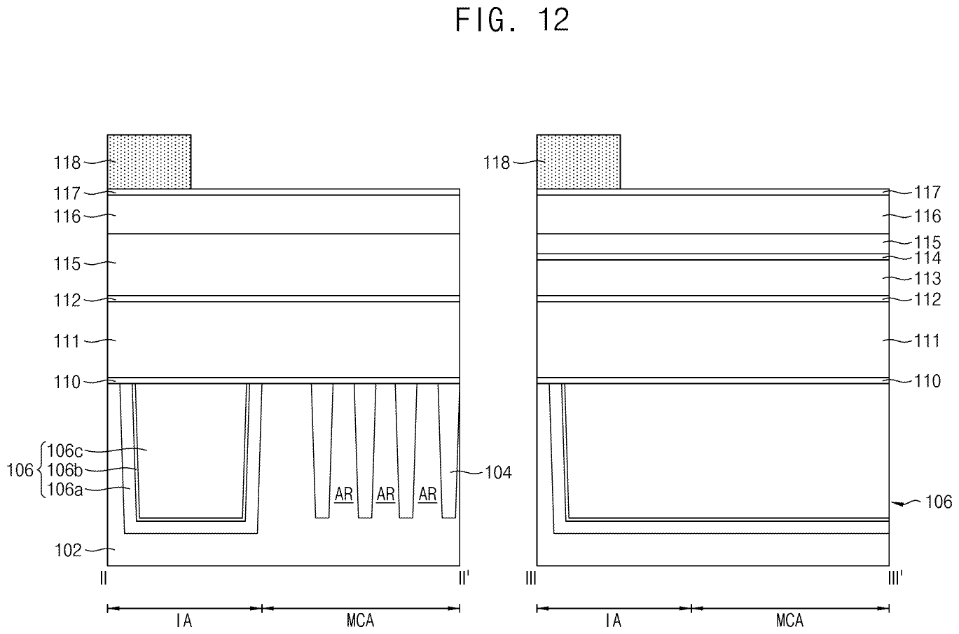

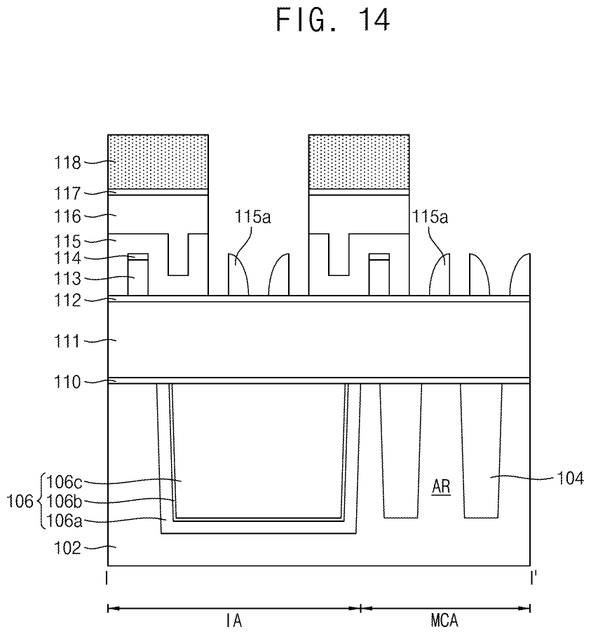

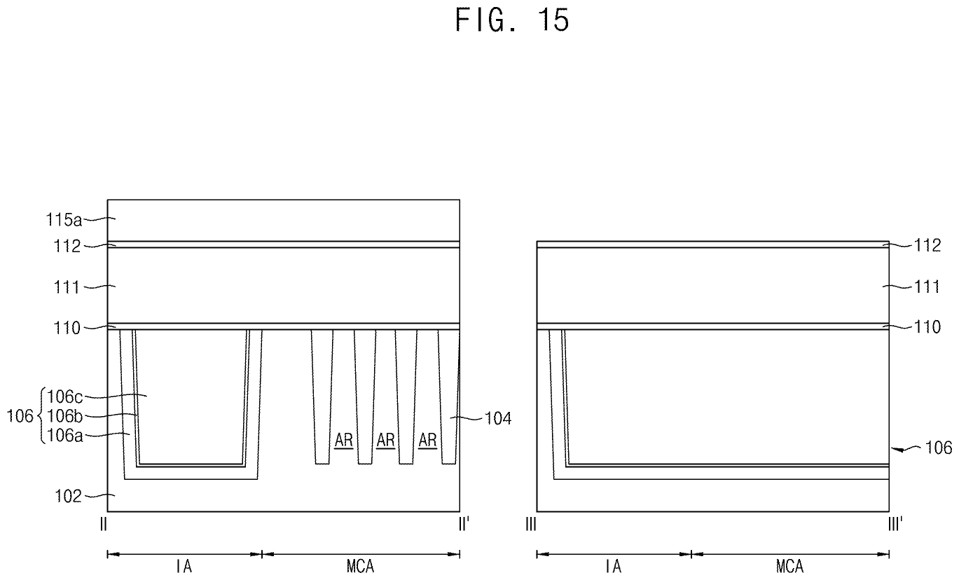

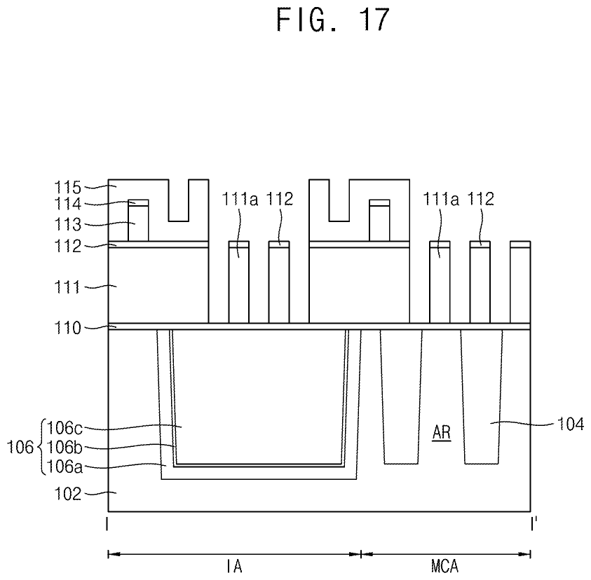

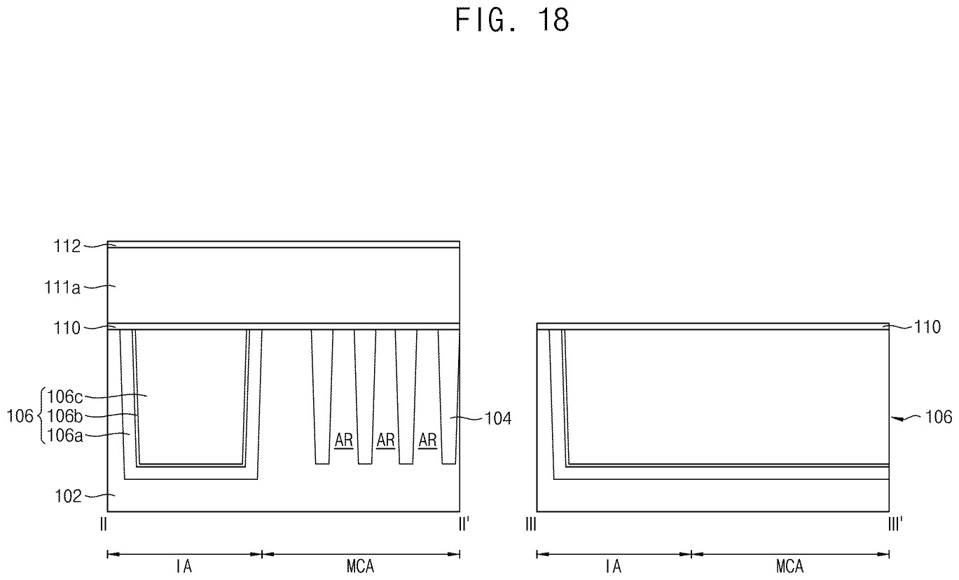

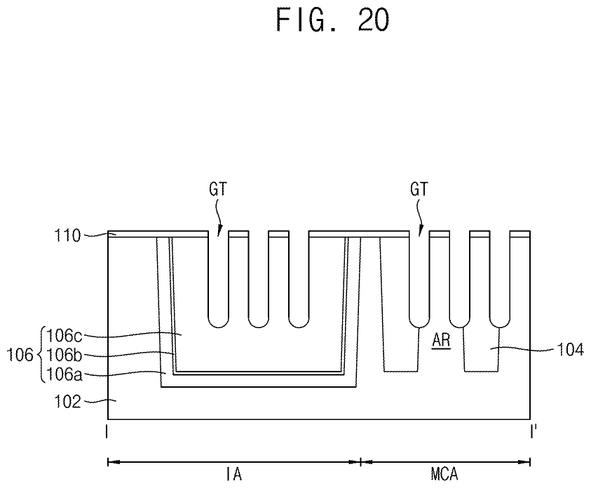

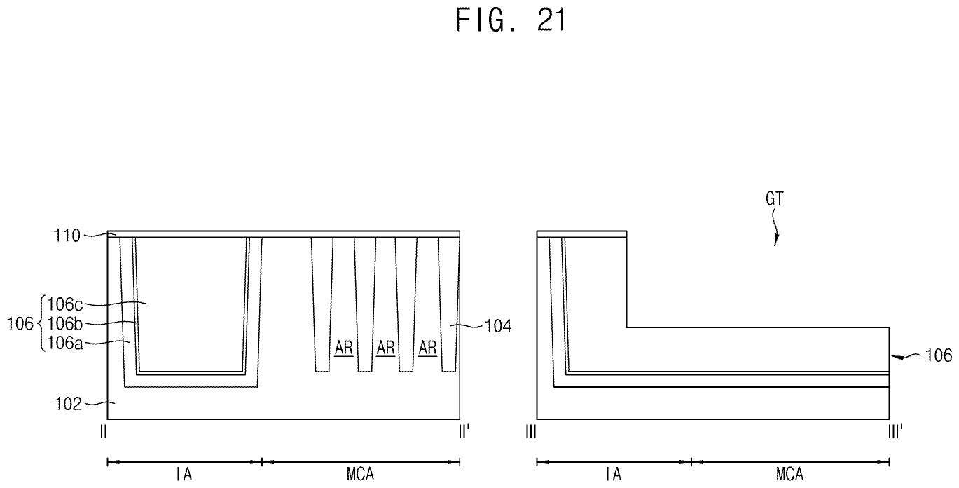

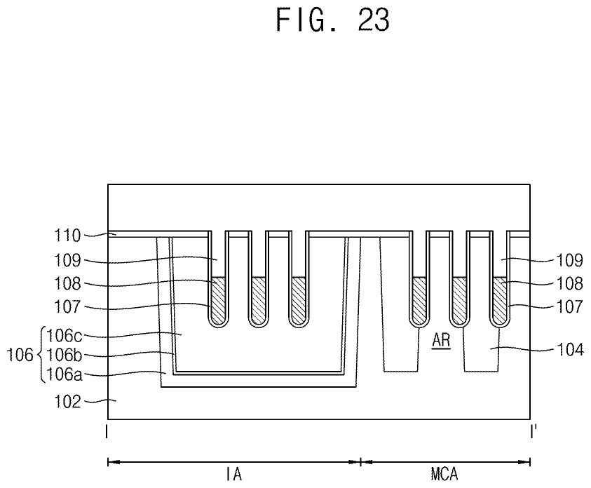

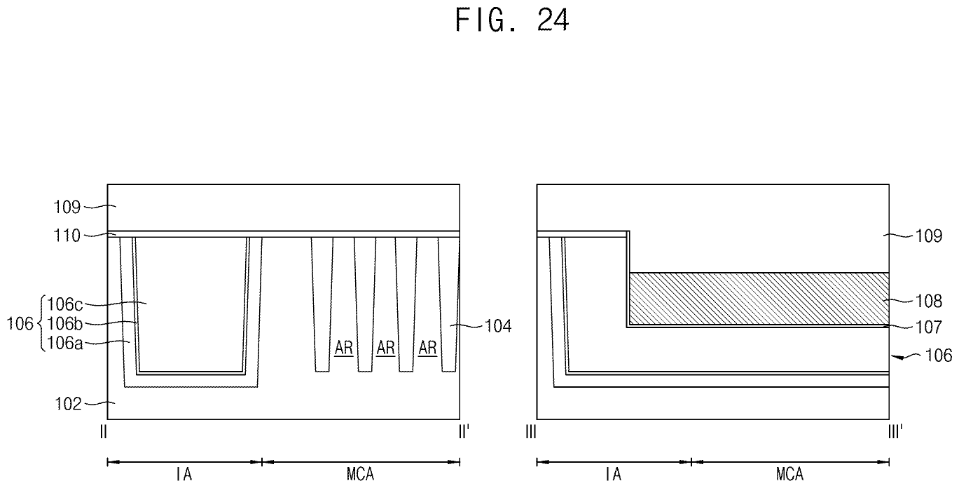

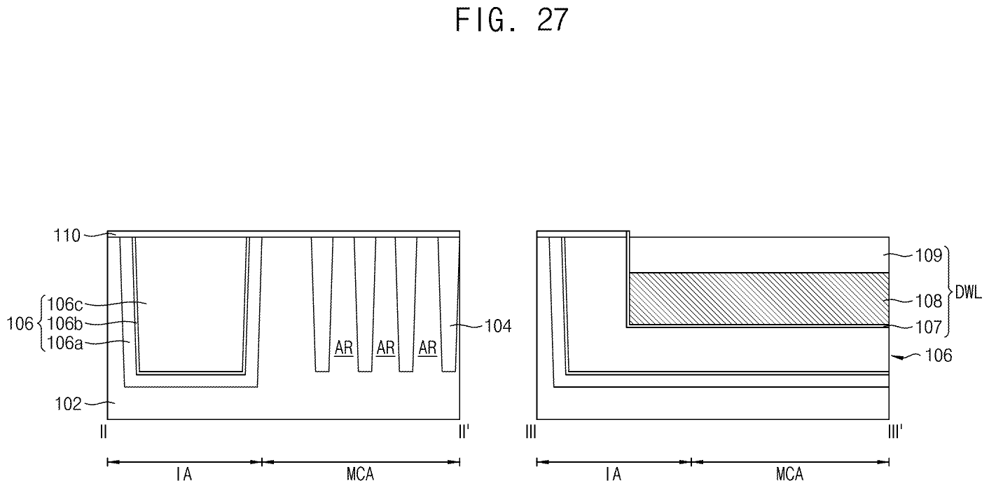

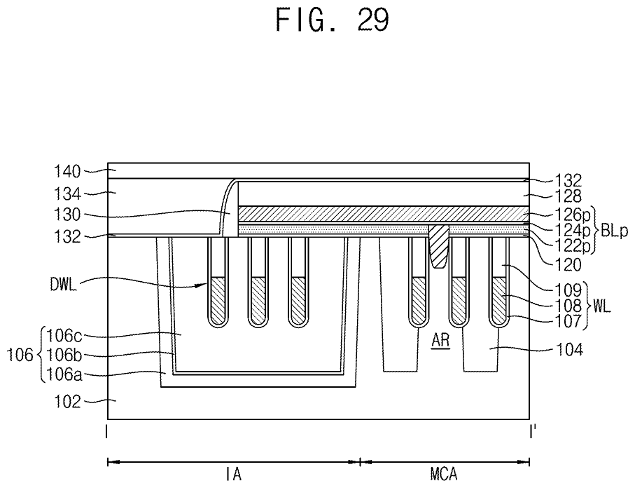

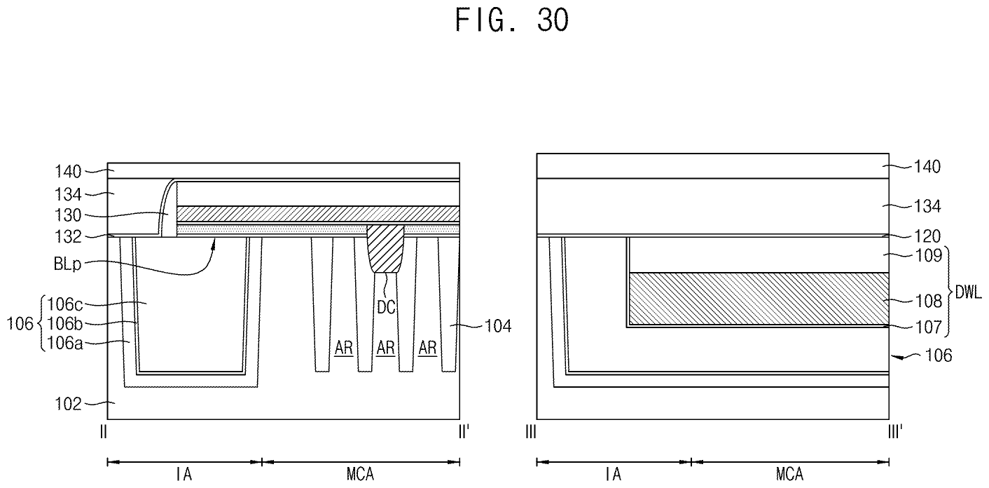

FIGS. 4 to 33 are plan views and vertical cross-sectional views illustrating, in process order, a method of manufacturing a semiconductor device according to an example embodiment of the inventive concepts. FIGS. 4, 7, 10, 13, 16, 19, 22, 25, 28, and 31 are plan views. FIGS. 5, 8, 11, 14, 17, 20, 23, 26, 29, and 32 are vertical cross-sectional views taken along line I-I′ in FIGS. 4, 7, 10, 13, 16, 19, 22, 25, 28, and 31, respectively. FIGS. 6, 9, 12, 15, 18, 21, 24, 27, 30, and 33 are vertical cross-sectional views taken along lines II-II′ and III-III′ in FIGS. 4, 7, 10, 13, 16, 19, 22, 25, 28, and 31, respectively.

Referring to FIGS. 4 to 6, a device isolation layer 104 and an area isolation layer 106 may be formed at (e.g., in/on) a substrate 102. The substrate 102 may include a cell area MCA and an interface area IA. The interface area IA may surround the cell area MCA, and may be disposed between the cell area MCA and a peripheral circuit area (not shown). The device isolation layer 104 may be disposed in the cell area MCA of the substrate 102, and the area isolation layer 106 may be disposed in the interface area IA of the substrate 102.

The device isolation layer 104 and the area isolation layer 106 may be formed by forming a trench at a top surface of the substrate 102, and filling the trench with an insulating material. The device isolation layer 104 may define active regions AR in the cell area MCA. For example, the active regions AR may correspond to a portion of the top surface of the substrate 102 surrounded by the device isolation layer 104. When viewed in a plan view, the active regions AR may have a bar shape having a shorter axis and a longer axis, and may be spaced apart from one another. The device isolation layer 104 may include silicon oxide, silicon nitride, silicon oxynitride, or a combination thereof. The device isolation layer 104 may be constituted by a single layer or multiple layers.

The area isolation layer 106 may define the interface area IA. For example, when viewed in a cross-sectional view, an area, in which the area isolation layer 106 is disposed, and an area opposite to the cell area MCA with reference to the area isolation layer 106 may be referred to as the interface area IA. When viewed in a plan view, the area isolation layer 106 may surround the cell area MCA, and, for example, may extend in an x-direction and a y-direction. The area isolation layer 106 may be an insulating layer extending downwards from a level of the top surface of the substrate 102. When viewed in a cross-sectional view, the horizontal width and the depth of the area isolation layer 106 may be greater than the horizontal width and the depth of the device isolation layer 104. The area isolation layer 106 may include a first area isolation layer 106a, a second area isolation layer 106b and a third area isolation layer 106c which are sequentially stacked. The first area isolation layer 106a and the second area isolation layer 106b may be conformally formed along an inner wall of the trench, at which the area isolation layer 106 is formed, and the third area isolation layer 106c may fill the trench. The first area isolation layer 106a and the third isolation layer 106c may include silicon oxide, and the second area isolation layer 106b may include silicon nitride.

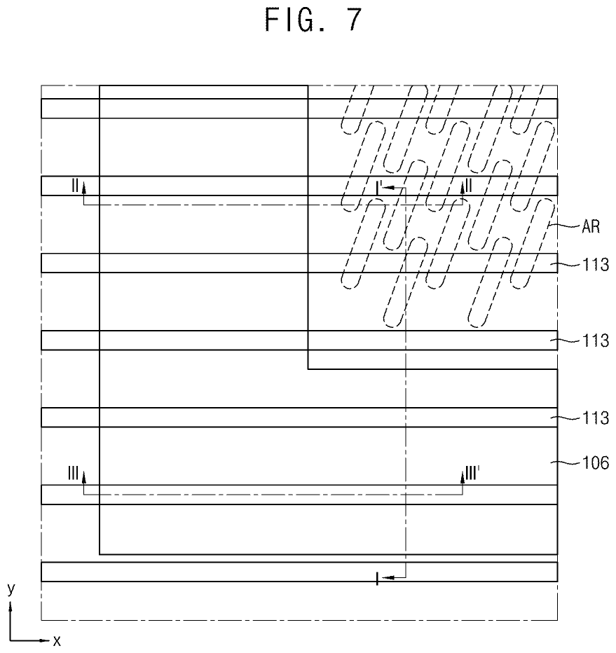

Referring to FIGS. 7 to 9, an insulating layer 110, a mask layer 111, and an etch stop layer 112 may be sequentially stacked on the substrate 102. The insulating layer 110, the mask layer 111, and the etch stop layer 112 may be formed in the cell region MCA and the interface area IA. The insulating layer 110 may include silicon oxide, the mask layer 111 may include an amorphous carbon layer (ACL), and the etch stop layer 112 may include silicon oxynitride (SiON).

After formation of the etch stop layer 112, a sacrificial pattern 113 and an etch stop pattern 114 may be formed on the etch stop layer 112. The sacrificial pattern 113 and the etch stop pattern 114 may be formed by depositing a sacrificial material and an etch stop material on the etch stop layer 112, and then anisotropically etching the sacrificial material and the etch stop material. The sacrificial pattern 113 may be formed in the cell area MCA and the interface area IA. When viewed in a plan view, sacrificial patterns 113 may extend in the x-direction while being spaced apart from one another in the y-direction. The etch stop pattern 114 may include a material having etch selectivity with respect to the sacrificial pattern 113. For example, the sacrificial pattern 113 may include a spin-on hardmask (SOH), and the etch stop pattern 114 may include SiON.

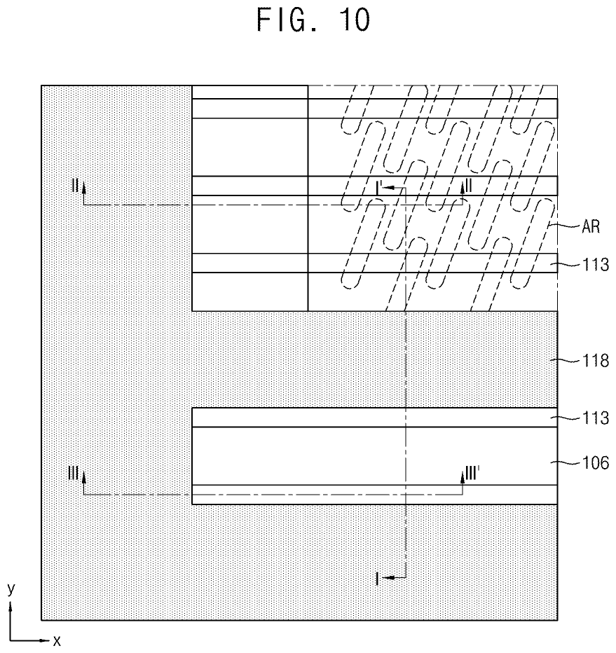

Referring to FIGS. 10 to 12, a spacer layer 115, a mask layer 116, and an etch stop layer 117 may be formed on the sacrificial pattern 113 and the etch stop pattern 114. The spacer layer 115, the mask layer 116, and the etch stop layer 117 may be formed in the cell area MCA and the interface area IA. The spacer layer 115 may be conformally formed along surfaces of the etch stop layer 112, the sacrificial pattern 113 and the etch stop pattern 114. For example, the spacer layer 115 may be formed by atomic layer deposition (ALD). The spacer layer 115 may be a layer for forming a fine line-and-space structure using double patterning technology (DPT) together with the sacrificial patterns 113. In an embodiment, the spacer layer 115 may have a thickness substantially equal to the horizontal width of the sacrificial pattern 113. The spacer layer 115 may include a material having etch selectivity with respect to the etch stop layer 112 and the sacrificial pattern 113. For example, the spacer layer 115 may include silicon oxide.

The mask layer 116 may cover the spacer layer 115, and the etch stop layer 117 may cover the mask layer 116. The etch stop layer 117 may include a material having etch selectivity with respect to the mask layer 116. For example, the mask layer 116 may include an SOH, and the etch stop layer 117 may include SiON.

After formation of the etch stop layer 117, a photoresist 118 may be formed on the etch stop layer 117. The photoresist 118 may expose a portion of the cell area MCA and a portion of the interface area IA. For example, the photoresist 118 may be disposed over the area isolation layer 106, and may expose a portion of the etch stop layer 117 on the area isolation layer 106. An exposed portion of the etch stop layer 117 may be spaced apart from the cell area MCA in the y-direction.

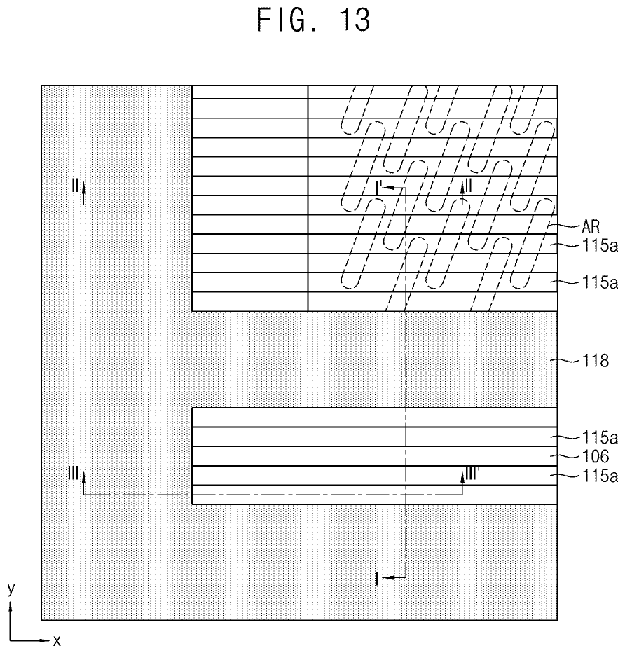

Referring to FIGS. 13 to 15, the portion of the etch stop layer 117 exposed by the photoresist 118 and the mask layer 116 may be etched. The etching process may be an anisotropic etching process, and the spacer layer 115 may be exposed.

After etching of the mask layer 116, the spacer layer 115 may be anisotropically etched, thereby forming a spacer 115a. For example, a portion of the spacer layer 115 formed on top surfaces of the etch stop layer 112 and the sacrificial patterns 113 may be etched through execution of an etch-back process. Portions of the spacer layer 115 at side surfaces of the sacrificial patterns 113 may remain without being removed and, as such, spacers 115a may be formed. When viewed in a plan view, the spacers 115a may extend in the x-direction in the cell area MCA and the interface area IA.

After formation of the spacer 115a, the sacrificial pattern 113 and the etch stop pattern 114 may be selectively removed and, as such, portions of a top surface of the etch stop layer 112 may be exposed. Portions of the sacrificial pattern 113, the etch stop pattern 114, the spacer layer 115, the mask layer 116 and the etch stop layer 117 not exposed by the photoresist 118 may not be removed.

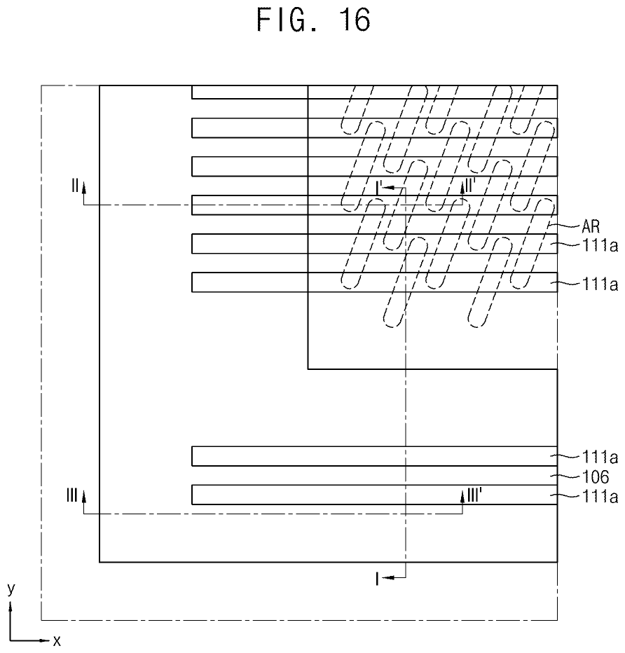

Referring to FIGS. 16 to 18, the mask layer 116, the etch stop layer 117, and the photoresist 118 may be removed. Thereafter, an anisotropic etching process using the spacers 115a as an etch mask may be performed. The mask layer 111 may be etched at portions thereof not covered by the spacer layer 115 and the spacers 115a and, as such, a mask pattern 111a may be formed. In addition, portions of the insulating layer 110 may be exposed by the etching process. When viewed in a plan view, the mask pattern 111a may extend in the x-direction in the cell area MCA and the interface area IA.

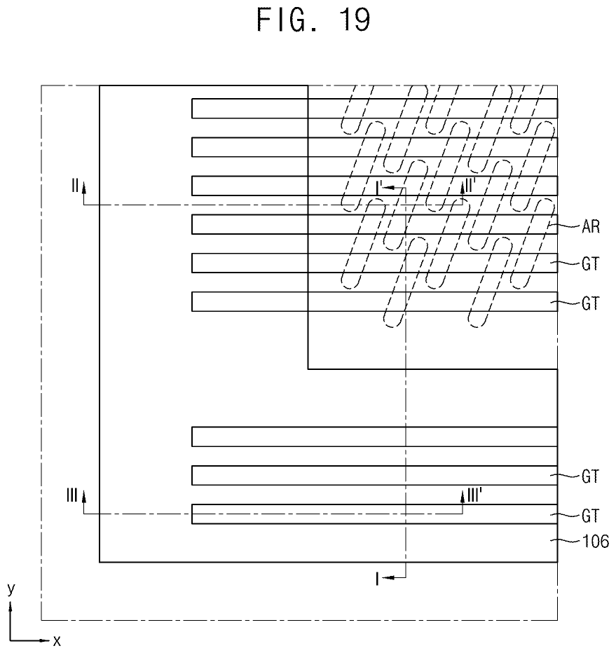

Referring to FIGS. 19 to 21, an anisotropic etching process using the mask pattern 111a as an etch mask may be performed. The mask layer 111, the etch stop layer 112, the sacrificial pattern 113, the etch stop pattern 114, and the spacer layer 115 may be removed. Gate trenches GT extending in the x-direction may be formed in the cell area MCA and the interface area IA by the etching process. The gate trenches GT may be spaced apart from one another in the y-direction. The gate trenches GT may overlap with the active area AR in the cell area MCA, and the gate trenches GT in the cell area MCA may further extend to the interface area IA in the x-direction. Gate trenches GT may also be formed in the area isolation layer 106 spaced apart from the cell area MCA in the y-direction. In an embodiment, the gate trench GT in the area isolation layer 106 may be formed to be deeper than the gate trench GT in the cell area MCA.

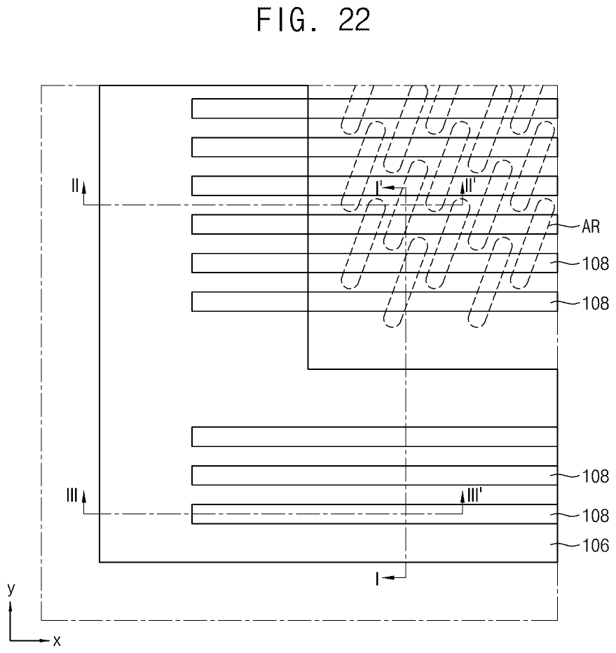

Referring to FIGS. 22 to 24, a gate dielectric layer 107, a gate conductive layer 108, and a gate capping layer 109 may be formed within the gate trench GT. The gate dielectric layer 107 may be conformally deposited along an inner wall of the gate trench GT. The gate conductive layer 108 may be formed on the gate dielectric layer 107, and may fill a lower portion of the gate trench GT. The gate capping layer 109 may be formed on the gate conductive layer 108, and may fill an upper portion of the gate trench GT. The gate capping layer 109 may also be formed on the substrate 102, and a portion of the gate capping layer 109 may cover the insulating layer 110.

The gate dielectric layer 107 may include silicon oxide, silicon nitride, silicon oxynitride, high-k dielectrics, or a combination thereof. The gate conductive layer 108 may include Ti, TiN, tantalum (Ta), tantalum nitride (TaN), W, tungsten nitride (WN), TiSiN, tungsten silicon nitride (WSiN), polysilicon, or a combination thereof. The gate capping layer 109 may include silicon oxide, silicon nitride, silicon oxynitride, or a combination thereof.

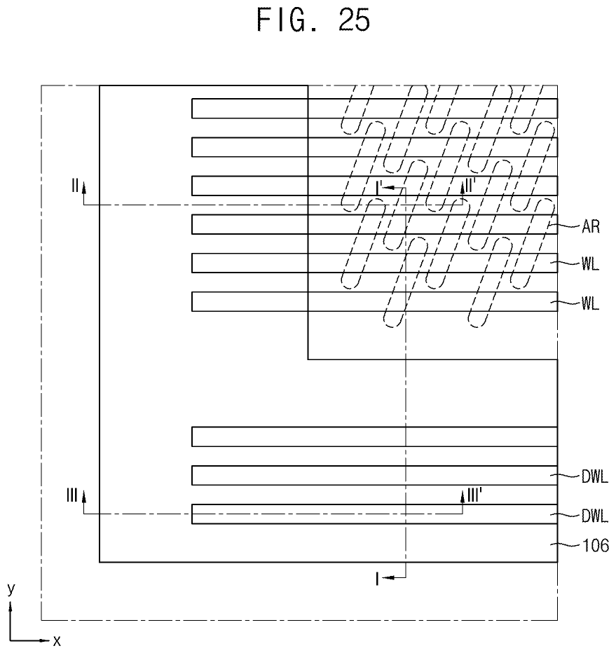

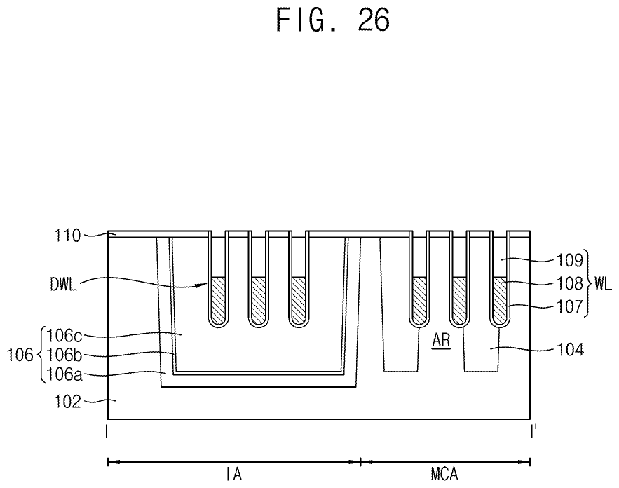

Referring to FIGS. 25 to 27, an etch-back process may be performed, thereby etching an upper portion of the gate capping layer 109 and exposing a top surface of the insulating layer 110. The gate capping layer 109 remaining without being removed may be disposed on the gate conductive layer 108 within the gate trench GT. In the cell area MCA, the gate dielectric layer 107, the gate conductive layer 108, and the gate capping layer 109 may constitute a gate structure WL. The gate structure WL may also extend in the x-direction and, as such, may also be disposed in the interface area IA. A dummy gate structure DWL may extend in the x-direction in the interface area IA. The dummy gate structure DWL may not be disposed in the cell area MCA when viewed in the cross section shown in FIG. 26, and may be spaced apart from the gate structure WL in the y-direction. The dummy gate structure DWL may have substantially the same structure as the gate structure WL. When viewed in a plan view, gate structures WL may be disposed to be spaced apart from one another by a uniform distance in the y-direction, and dummy gate structures DWL may be disposed to be spaced apart from one another by a uniform distance in the y-direction. The distance among the gate structures WL may be substantially equal to the distance among the dummy gate structures DWL.

In an embodiment, after formation of the gate structures WL, impurity ions may be implanted in portions of the active region AR of the substrate 102 at opposite sides of each gate structure WL, thereby forming a source region and a drain region. In another embodiment, the impurity ion implantation process for formation of the source region and the drain region may be performed before formation of the gate structures WL.

After formation of the gate structures WL, the insulating layer 110 on the substrate 102 may be removed by an etch-back process. When the insulating layer 110 on the area isolation layer 106 is, instead, not etched in the etch-back process, the insulating layer 110 may be non-uniformly removed due to a surface difference between a portion of the insulating layer 110 in the cell area MCA and a portion of the insulating layer 110 in the interface area IA. Then, the insulating layer 110 in the interface area IA may remain without being etched, or portions of the device isolation layer 104 in the cell area MCA may be etched. In this case, the height of a bit line structure BLS, which will be described later, may be non-uniform. However, as shown in FIG. 13, the photoresist 118 may not only expose the cell region MCA, but may also expose the interface area IA and, as such, a portion of the insulating layer 110 on the area isolation layer 106 may also be etched when the gate trench GT is formed. Accordingly, in the etch-back process, the insulating layer 110 may be uniformly etched, and reliability of the resultant device may be enhanced.

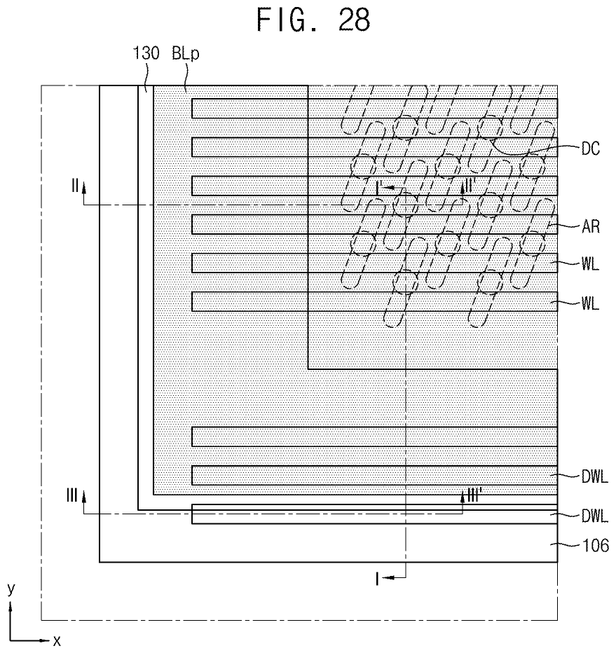

Referring to FIGS. 28 to 30, a buffer layer 120, a bit line material layer BLp, a first capping layer 128, an edge spacer 130, an insulating liner 132, an interlayer insulating layer 134, and a second capping layer 140 may be formed on the substrate 102. The bit line material layer BLp may include a first conductive material layer 122p, a second conductive material layer 124p, and a third conductive material layer 126p. The bit line material layer BLp may be formed by forming the buffer layer 120 on the substrate 102, sequentially stacking the first conductive material layer 122p, the second conductive material layer 124p, the third conductive material 126p and the first capping layer 128 on the buffer layer 120, and then patterning the resultant stack structure such that a first portion of the interface area IA is exposed. The bit line material layer BLp may cover the cell area MCA, and may cover a second portion of the interface area IA.

Before formation of the second conductive material 124p, a direct contact DC may be formed. The direct contact DC may be formed by forming the first conductive material layer 122p, etching the first conductive material layer 122p, forming a recess in the top surface of the substrate 102, filling the recess with a conductive material, and then performing a planarization process. A top surface of the direct contact DC may be coplanar with a top surface of the first conductive material layer 122p. The direct contact DC may be formed in the active region AR, and, for example, may contact the source region of the active region AR.

The buffer layer 120 may include silicon oxide, silicon nitride, silicon oxynitride, high-k dielectrics, or a combination thereof. The first conductive material layer 122p may include polysilicon. The direct contact DC may include silicon (Si), germanium (Ge), W, WN, cobalt (Co), nickel (Ni), aluminum (Al), molybdenum (Mo), ruthenium (Ru), Ti, TiN, Ta, TaN, copper (Cu), or a combination thereof. In some embodiments, the direct contact DC may include polysilicon. Each of the second conductive material layer 124p and the third conductive material layer 126p may include TiN, TiSiN, W, tungsten silicide, or a combination thereof. The first capping layer 128 may include silicon nitride.

After formation of the bit line material layer BLp, the edge spacer 130 may be formed. The edge spacer 130 may be formed by depositing an insulating layer covering the substrate 102 and the bit line material layer BLp, and then etching the insulating layer by an etching process. The edge spacer 130 may cover an end surface of the bit line material layer BLp, and may be disposed on the area isolation layer 106 in the interface area IA. The edge spacer 130 may include silicon oxide, silicon nitride, silicon oxynitride, or a combination thereof. In an embodiment, the edge spacer 130 may include silicon oxide.

After formation of the edge spacer 130, an insulating material may be deposited, thereby forming the insulating liner 132. The insulating liner 132 may be conformally formed on the cell region MCA and the interface area IA. An interlayer insulating layer 134 may be formed by depositing an insulating material, and then performing a planarization process such that a top surface of the insulating liner 132 is exposed. A top surface of the interlayer insulating layer 134 may be coplanar with the top surface of the insulating liner 132 on the first capping layer 128, without being limited thereto. In an embodiment, a portion of the insulating liner 132 on the first capping layer 128 may be removed by the planarization process, and the top surface of the interlayer insulating layer 134 may be coplanar with the top surface of the first capping layer 128. The interlayer insulating layer 134 may not be disposed in the cell area MCA, and may be disposed in the interface area IA. The insulating liner 132 may include silicon nitride, and the interlayer insulating layer 134 may include silicon oxide.

The second capping layer 140 may be formed by depositing an insulating layer covering the insulating liner 132 and the interlayer insulating layer 134. The second capping layer 140 may be formed in the cell area MCA and the interface area IA. The second capping layer 140 may include silicon oxide, silicon nitride, silicon oxynitride, or a combination thereof. In an embodiment, the second capping layer 140 may include silicon nitride.

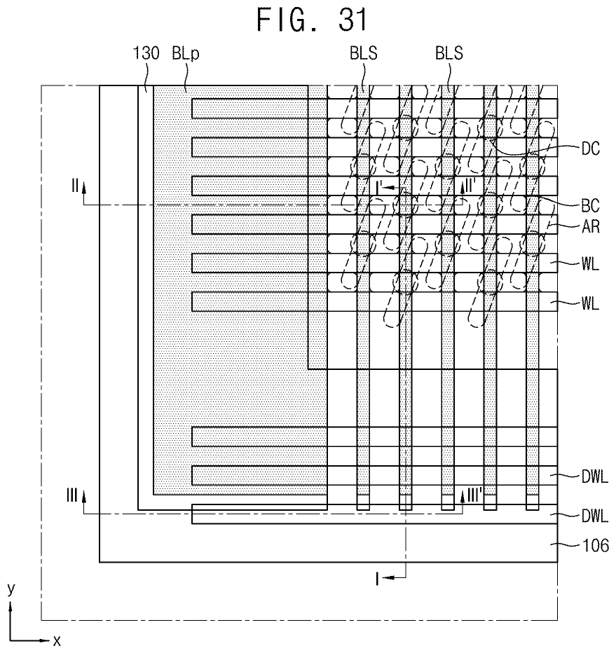

Referring to FIGS. 31 to 33, the buffer layer 120, the first conductive material layer 122p, the second conductive material layer 124p, the third conductive material layer 126p, the first capping layer 128, and the second capping layer 140 may be etched to form a trench T extending in the y-direction and, as such, a bit line structure BLS may be formed. The first conductive layer 122, the second conductive layer 124, and the third conductive layer 126 may constitute the bit line structure BLS. When viewed in a plan view, the bit line structure BLS may have a bar shape extending in the y-direction. The bit line structure BLS may be disposed in the cell area MCA, and may further extend to the interface area IA. The portion of the bit line material layer BLp that is not etched may be spaced apart from the bit line structure BLS in the x-direction, and may be disposed in the interface area IA.

After formation of the bit line structure BLS, insulating spacers 142 may be formed at side surfaces of the bit line structure BLS. The insulating spacers 142 may be formed by depositing an insulating material covering the bit line structure BLS and an inner wall of the trench T, and then anisotropically etching the insulating material. The insulating spacers 142 may cover side surfaces of the bit line structure BLS, and may also cover side surfaces of the direct contact DC. The insulating spacers 142 may be constituted by a single layer or multiple layers. The insulating spacers 142 may include silicon oxide, silicon nitride, silicon oxynitride, or a combination thereof.

After formation of the insulating spacers 142, buried contacts BC may be formed at the side surfaces of the bit line structure BLS. The buried contacts BC may be formed by forming a sacrificial layer (not shown) extending in the y-direction while filling the trenches T at the side surfaces of the bit line structures BLS, forming fence insulating layers (not shown) at portions of the sacrificial layer vertically overlapping with the gate structures WL, removing the sacrificial layer, and then depositing a conductive material at opposite sides of the bit line structures BLS.

After formation of the buried contact BC, an etch-back process for etching an upper portion of the buried contact BC may further be performed. For example, a top surface of the buried contact BC may be disposed at a lower level than a top surface of the bit line structure BLS. The buried contact BC may extend into the substrate 102. For example, a lower end of the buried contact BC may be disposed at a lower level than the top surface of the substrate 102, and may contact the drain region of the active region AR. An insulating spacer 142 may be disposed between the buried contact BC and the bit line structure BLS. The insulating spacer 142 may electrically insulate the buried contact BC and the bit line structure BLS from each other. The buried contact BC may include polysilicon.

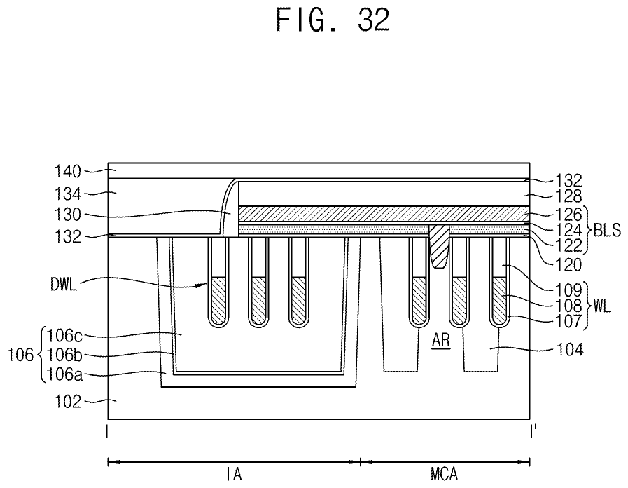

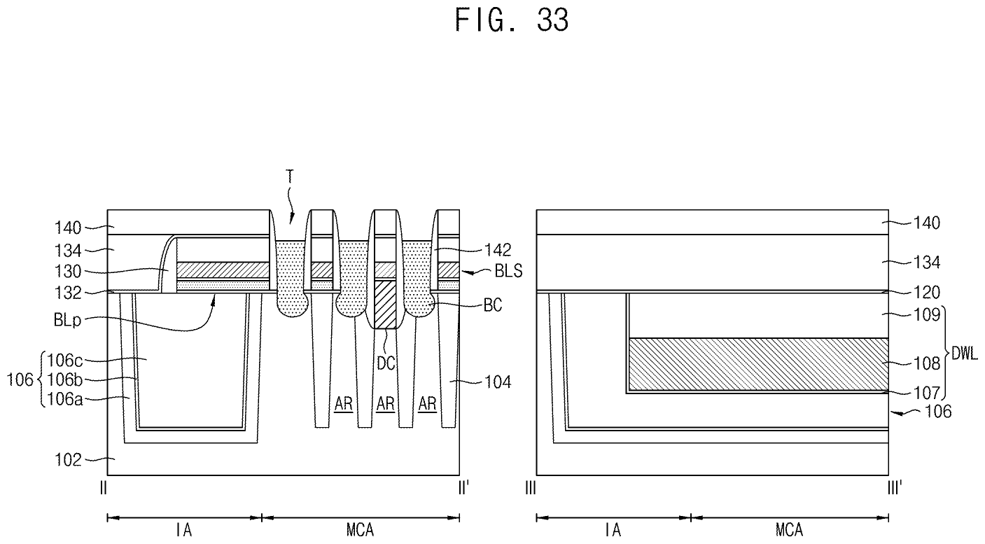

Again referring to FIGS. 1 to 3, a barrier pattern 150, a conductive pattern 152, and an insulating structure 155 may be formed. The barrier pattern 150 and the conductive pattern 152 may be formed by conformally forming a barrier material on the resultant structure of FIGS. 32 and 33, forming a conductive material on the barrier material, and patterning the barrier material and the conductive material. For example, the barrier pattern 150 may be formed along the bit line structure BLS, the trench T, and the second capping layer 140. The conductive pattern 152 may be disposed on a barrier layer. A top surface of the conductive pattern 152 may correspond to the landing pad LP shown in FIG. 1. The conductive pattern 152 may be electrically connected to the active region AR via the buried contact BC. In an embodiment, before formation of the barrier material, a process for forming a metal silicide layer on the buried contact BC may further be performed.

The barrier pattern 150 may include metal silicide such as cobalt silicide, nickel silicide, and manganese silicide. The conductive pattern 152 may include polysilicon, metal, metal silicide, conductive metal nitride, or a combination thereof. In an embodiment, the conductive pattern 152 may include tungsten.

The insulating structure 155 may be formed by etching the barrier material and the conductive material, and then filling with an insulating material. The insulating structure 155 may be disposed between adjacent ones of conductive patterns 152, and may electrically insulate the adjacent conductive patterns 152 from each other. A top surface of the insulating structure 155 and a top surface of the conductive pattern 152 may be coplanar. The insulating structure 155 may also be disposed in the interface area IA. For example, the insulating structure 155 may contact the top surface of the second capping layer 140 in the interface area IA. The insulating structure 155 may include silicon oxide, silicon nitride, silicon oxynitride, or a combination thereof.

Subsequently, a lower electrode 160, a capacitor dielectric layer 162, an upper electrode 164, and an upper insulating layer 170 may be formed and, as such, a semiconductor device 100 may be formed. The lower electrode 160 may be disposed to correspond to (e.g., to be electrically connected to) the conductive pattern 152. For example, the lower electrode 160 may contact the top surface of the conductive pattern 152, and may be electrically connected to the drain region via the conductive pattern 152 and the buried contact BC. In an embodiment, the lower electrode 160 may have a pillar shape, without being limited thereto. In another embodiment, the lower electrode 160 may have a cylindrical shape or a hybrid shape of a pillar shape and a cylindrical shape.

The capacitor dielectric layer 162 may be conformally formed along surfaces of the conductive pattern 152, the insulating structure 155 and the lower electrode 160. The upper electrode 164 may be formed on the capacitor dielectric layer 162. The lower electrode 160, the capacitor dielectric layer 162, and the upper electrode 164 may constitute a capacitor structure of the semiconductor device 100. The upper insulating layer 170 may be formed at the same level as the upper electrode 164 in the interface area IA.

The lower electrode 160 may include metal such as Ti, W, Ni, and Co or metal nitride such as TiN, TiSiN, TiAlN, TaN, TaSiN, WN, etc. In an embodiment, the lower electrode 160 may include TiN. The capacitor dielectric layer 162 may include metal oxide such as HfO₂, ZrO₂, Al₂O₃, La₂O₃, Ta₂O₃, and TiO₂, a dielectric material having a perovskite structure such as SrTiO₃(STO), BaTiO₃, PZT and PLZT, or a combination thereof. The upper electrode 164 may include metal such as Ti, W, Ni and Co or metal nitride such as TiN, TiSiN, TiAlN, TaN, TaSiN, WN, etc.

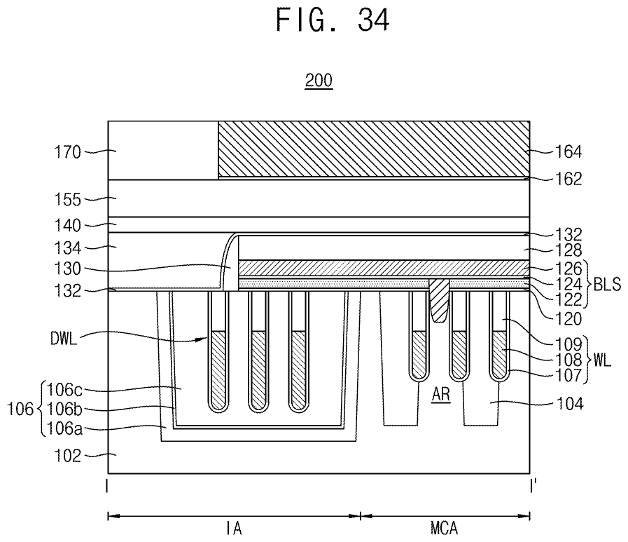

FIG. 34 is a vertical cross-sectional view of a semiconductor device according to an example embodiment of the inventive concepts.

Referring to FIG. 34, a semiconductor device 200 may include a dummy gate structure DWL disposed in an area isolation layer 106. In an embodiment, the height of the dummy gate structure DWL may be greater than the height of a gate structure WL. For example, a top surface of the dummy gate structure DWL and a top surface of a gate structure WL may be disposed at the same level, and a lower end of the dummy gate structure DWL may be disposed at a lower level than a lower end of the gate structure WL. However, the lower end of the dummy gate structure DWL may be disposed at a higher level than a lower surface of an area isolation layer 106. A top surface of a gate conductive layer 108 of the dummy gate structure DWL may be disposed at a lower level than a top surface of a gate conductive layer 108 of the gate structure WL, without being limited thereto. In an embodiment, the top surface of the gate conductive layer 108 of the dummy gate structure DWL may be disposed at the same level as the top surface of the gate conductive layer 108 of the gate structure WL.

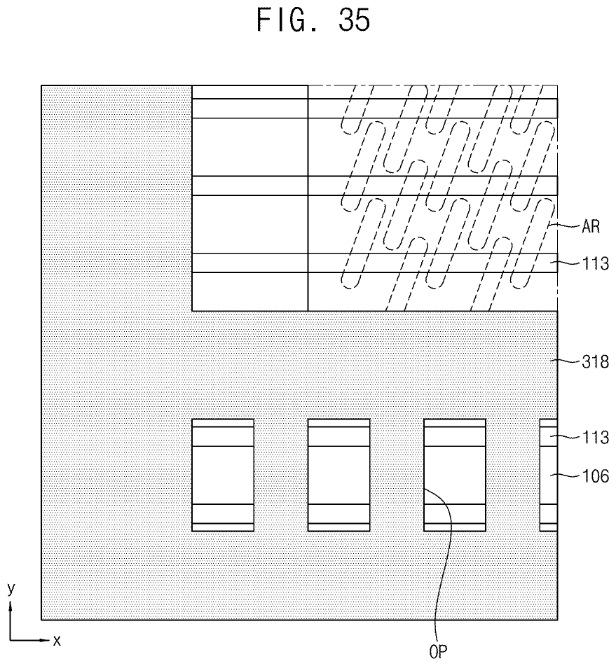

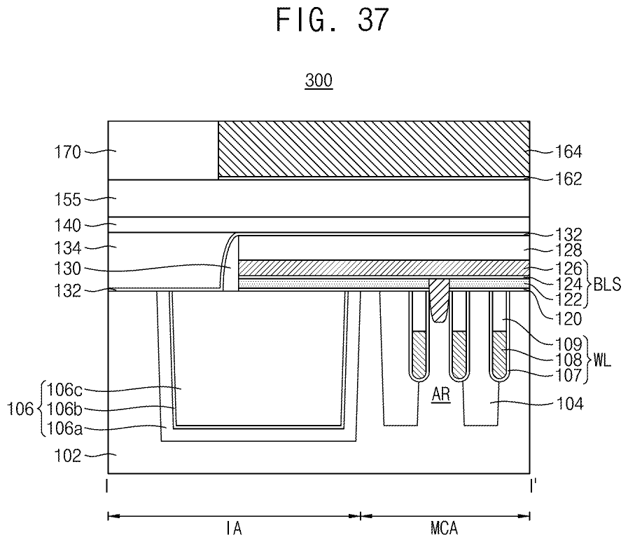

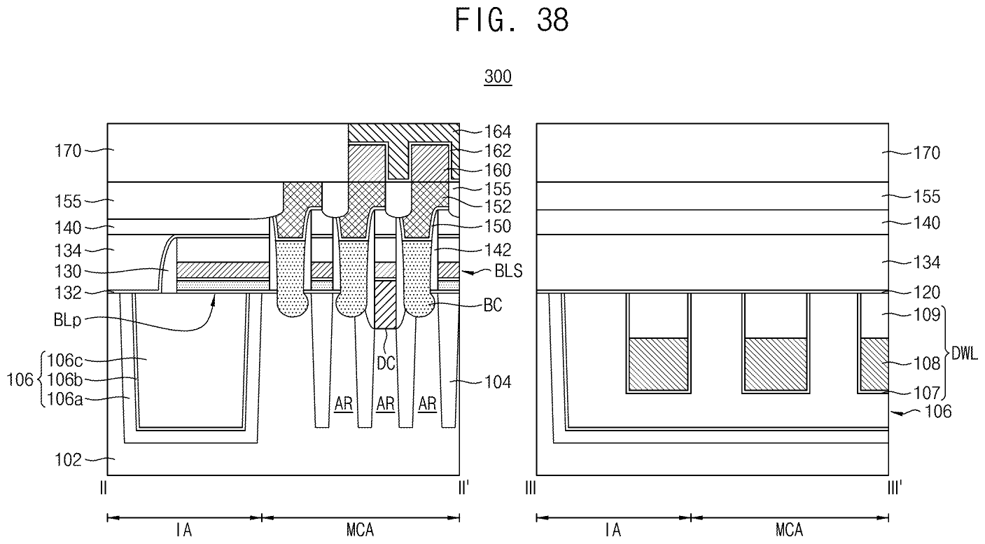

FIGS. 35 to 38 are plan views and vertical cross-sectional views of a semiconductor device according to an example embodiment of the inventive concepts.

Referring to FIGS. 10 and 35, a photoresist 318 may include openings OP that expose an area isolation layer 106. The openings OP may be spaced apart from one another in an x-direction. A space between the openings OP may be covered by the photoresist 318.

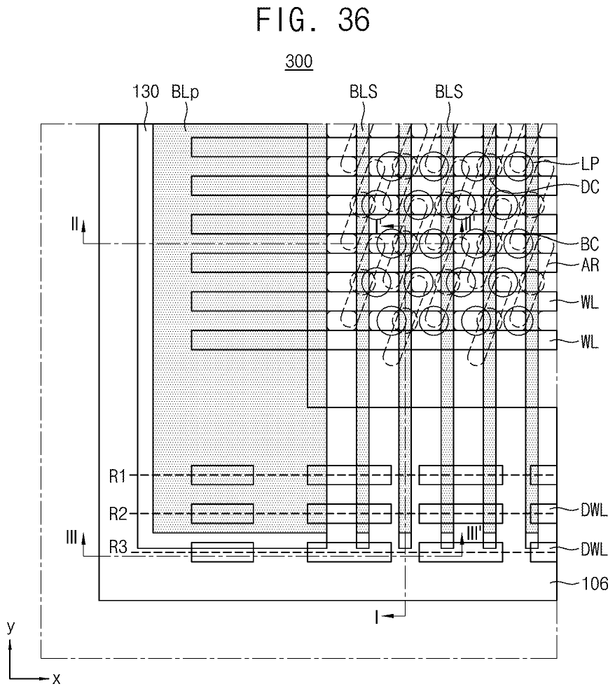

FIGS. 36 to 38 show a semiconductor device 300 formed by performing the process shown in FIGS. 13 to 27 using the photoresist 318 shown in FIG. 35.

Referring to FIGS. 36 to 38, the semiconductor device 300 may include dummy gate structures DWL buried in an area isolation layer 106. For example, the dummy gate structures DWL may extend vertically below a level of the top surface of the area isolation layer 106 and below a level of the top surface of the substrate 102. In some embodiments, the top surface of the area isolation layer 106 may be coplanar with the top surface of the substrate 102. The dummy gate structures DWL may be arranged in columns parallel to a y-direction and in rows parallel to an x-direction. In an embodiment, the dummy structures DWL may be disposed in the form of a lattice structure. For example, the dummy gate structures DWL may include a first row R1, a second row R2, and a third row R3. The dummy gate structures DWL in each of the rows R1, R2 and R3 may be spaced apart from one another in the x-direction, and may have the same length. Here, the length of the dummy gate structure DWL may mean a length extending in the x-direction. Each dummy gate structure DWL in each of the rows R1, R2 and R3 may be aligned with the dummy gate structure DWL adjacent thereto in the y-direction. For example, a y-directional axis of each dummy gate structure DWL in the first row R1 may be disposed on the same line as a y-directional axis of the dummy gate structure DWL in the second row R2 adjacent to the dummy gate structure DWL in the first row R1 in the y-direction. The area isolation layer 106 may be interposed among the y-directional dummy gate structures DWL.

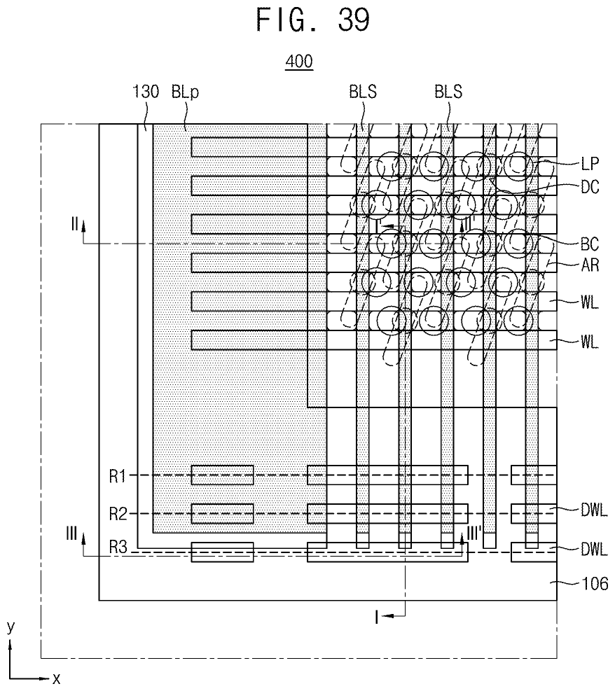

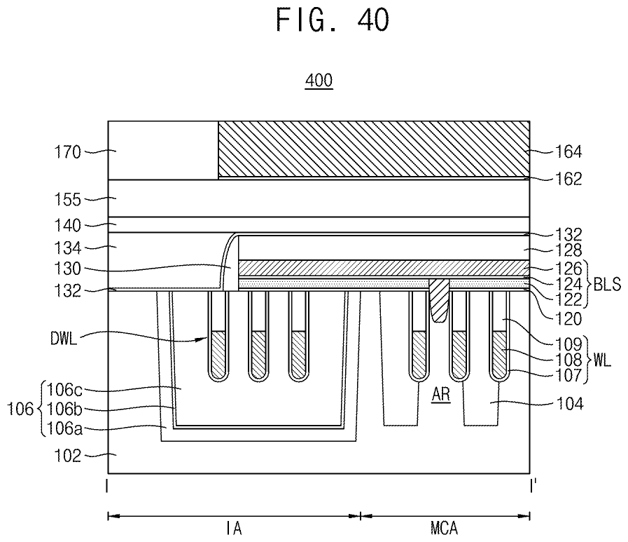

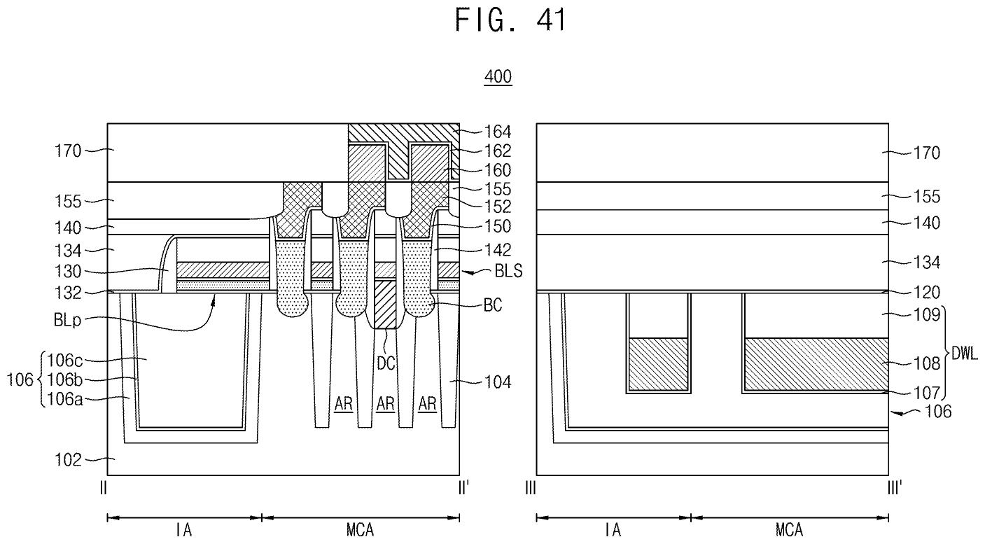

FIGS. 39 to 41 are plan views and vertical cross-sectional views of a semiconductor device according to an example embodiment of the inventive concepts.

Referring to FIGS. 39 to 41, a semiconductor device 400 may include dummy gate structures DWL buried in an area isolation layer 106. The dummy gate structures DWL may include a first row R1, a second row R2, and a third row R3. In an embodiment, the dummy gate structures DWL may have different lengths. For example, the first row R1 may include a dummy gate structure DWL having a relatively small length and a dummy gate structure DWL having a relatively great length.

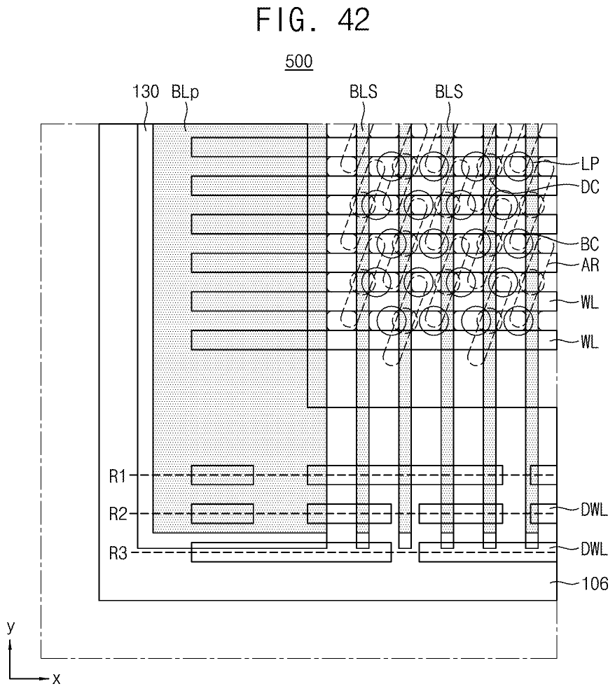

FIGS. 42 to 44 are plan views and vertical cross-sectional views of semiconductor devices according to example embodiments of the inventive concepts.

Referring to FIG. 42, a semiconductor device 500 may include dummy gate structures DWL buried in an area isolation layer 106. The dummy gate structures DWL may include a first row R1, a second row R2, and a third row R3. In an embodiment, the dummy gate structures DWL adjacent to each other in a y-direction may have different lengths. For example, the first row R1 and the third row R3 may include a dummy gate structure DWL having a relatively small length and a dummy gate structure DWL having a relatively great length. The dummy gate structures DWL in the second row R2 may have the same length. Each dummy gate structure DWL in the first row R1 may have a length different from that of the dummy gate structure DWL adjacent thereto from among the dummy gate structures DWL in the second row R2.

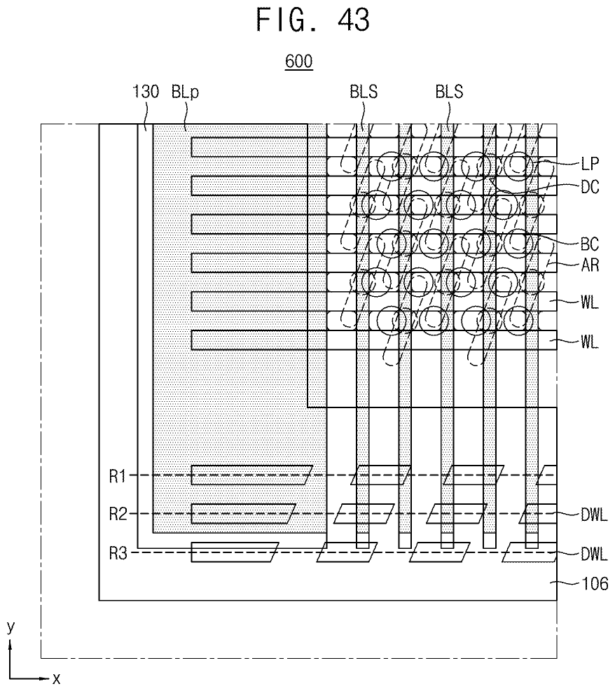

Referring to FIG. 43, a semiconductor device 600 may include dummy gate structures DWL buried in an area isolation layer 106. The dummy gate structures DWL may include a first row R1, a second row R2, and a third row R3. In an embodiment, when viewed in a plan view, the dummy gate structures DWL may have a parallelogram shape. Each dummy gate structure DWL in the first row R1 may be misaligned in a y direction and deviated (e.g., extending a different distance) in an x-direction from the dummy gate structure DWL in the second row R2 adjacent thereto in the y-direction. For example, the semiconductor device 600 may include a first dummy gate structure DWL in the first row R1, a second dummy gate structure DWL in the second row R2 adjacent to the first dummy gate structure DWL in the y direction, and a third dummy gate structure DWL in the third row R3 adjacent to the second dummy gate structure DWL. The first dummy gate structure DWL, the second dummy gate structure DWL, and the third dummy gate structure DWL may be misaligned from one another in the y direction while being disposed to be deviated from one another in the x-direction by a predetermined distance.

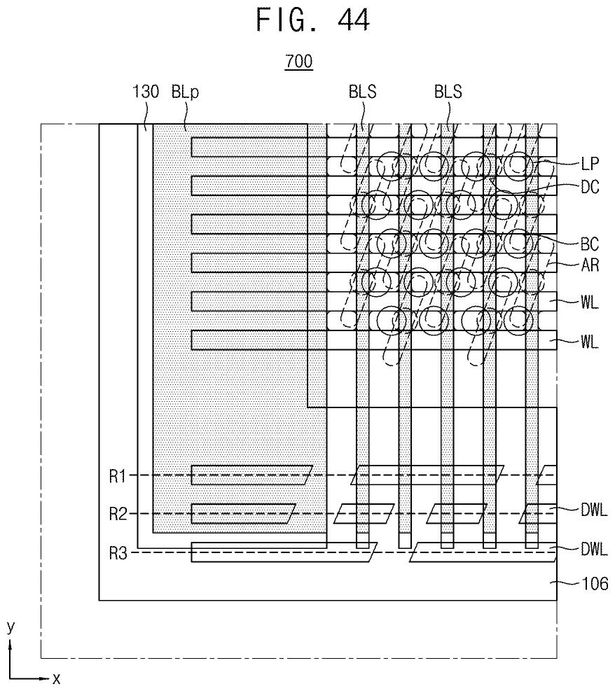

Referring to FIG. 44, a semiconductor device 700 may include dummy gate structures DWL buried in an area isolation layer 106. The dummy gate structures DWL may include a first row R1, a second row R2, and a third row R3. In an embodiment, the dummy gate structures DWL may have a parallelogram shape, and may have different lengths. For example, the first row R1 may include a dummy gate structure DWL having a relatively small length and a dummy gate structure DWL having a relatively great length.

In accordance with the example embodiments of the disclosure, a dummy gate structure is formed in an interface area simultaneously with formation of a gate structure in a cell region and, as such, it may be possible to reduce process deviation in a subsequent process and to enhance reliability of the resultant device.

While example embodiments of the disclosure have been described with reference to the accompanying drawings, it should be understood by those skilled in the art that various modifications may be made without departing from the scope of the invention. Therefore, the above-described embodiments should be considered in a descriptive sense only and not for purposes of limitation.

What is claimed is:

1. A semiconductor device comprising:
a substrate including a cell area and an interface area surrounding the cell area, the substrate including a device isolation layer defining an active region in the cell area and including an area isolation layer in the interface area;
a gate structure extending in the cell area in a first horizontal direction, the gate structure being buried in the substrate and intersecting the active region;
a bit line structure intersecting the gate structure and extending in a second horizontal direction intersecting the first horizontal direction; and
dummy gate structures extending in the interface area in the first horizontal direction and being spaced apart from one another in the second horizontal direction,
wherein the dummy gate structures are buried in the area isolation layer and are spaced apart from the gate structure in the second horizontal direction.

2. The semiconductor device according to claim 1,
wherein the dummy gate structures include a same material as the gate structure, and
wherein the area isolation layer extends continuously in the second horizontal direction to contact respective lower ends of the dummy gate structures.

3. The semiconductor device according to claim 2, wherein the gate structure and the dummy gate structures include a gate conductive layer, a gate capping layer on the gate conductive layer, and a gate dielectric layer surrounding side surfaces and lower surfaces of the gate conductive layer and the gate capping layer.

4. The semiconductor device according to claim 1, wherein respective widths of the dummy gate structures in the second horizontal direction are equal to a width of the gate structure in the second horizontal direction.

5. The semiconductor device according to claim 1,
wherein the gate structure further extends to the interface area, and
wherein the bit line structure extends continuously from the cell area to the interface area.

6. The semiconductor device according to claim 1, wherein a lower surface of the area isolation layer is lower than a lower surface of the device isolation layer.

7. The semiconductor device according to claim 1, wherein respective lower ends of the dummy gate structures are at a lower level than a lower end of the gate structure.

8. The semiconductor device according to claim 1, wherein the dummy gate structures are arranged in columns parallel to the second horizontal direction and rows parallel to the first horizontal direction.

9. The semiconductor device according to claim 8, wherein the dummy gate structures constitute a first row and a second row each including dummy gate structures spaced apart from one another in the first horizontal direction, and each of the dummy gate structures in the first row is aligned in the second horizontal direction with one dummy gate structure adjacent thereto from among the dummy gate structures in the second row.

10. The semiconductor device according to claim 9, wherein respective lengths of the dummy gate structures are equal.

11. The semiconductor device according to claim 9, wherein each dummy gate structure in the first row has a length equal to a length of one dummy gate structure adjacent thereto from among the dummy gate structures in the second row.

12. The semiconductor device according to claim 9, wherein the first row includes a first dummy gate structure having a first length, and a second dummy gate structure having a second length greater than the first length.

13. The semiconductor device according to claim 8, wherein the dummy gate structures constitute a first row and a second row each including dummy gate structures spaced apart from one another in the first horizontal direction, and each dummy gate structure in the first row has a length equal to a length of one dummy gate structure adjacent thereto from among the dummy gate structures in the second row.

14. The semiconductor device according to claim 8, wherein, when viewed in a plan view, the dummy gate structures have a parallelogram shape.

15. The semiconductor device according to claim 14, wherein:
the dummy gate structures constitute a first row, a second row and a third row each including dummy gate structures spaced apart from one another in the first horizontal direction;
the first row includes a first dummy gate structure;
the second row includes a second dummy gate structure adjacent to the first dummy gate structure;
the third row includes a third dummy gate structure adjacent to the second dummy gate structure; and
the first dummy gate structure, the second dummy gate structure, and the third dummy gate structure extend different respective distances in the first horizontal direction.

16. A semiconductor device comprising:
a substrate including a cell area and an interface area bordering the cell area;
a device isolation layer in the cell area and defining an active region of the substrate in the cell area;
an area isolation layer in the interface area;
gate structures extending in the cell area in a first horizontal direction, the gate structures extending below a level of a top surface of the substrate and intersecting the active region;
a bit line structure intersecting the gate structures and extending in a second horizontal direction intersecting the first horizontal direction; and
dummy gate structures extending in the interface area in the first horizontal direction and being spaced apart from one another by a first distance in the second horizontal direction,
wherein the dummy gate structures are spaced apart from the gate structures in the second horizontal direction, and a minimum distance between the dummy gate structures and the gate structures is greater than the first distance.

17. The semiconductor device according to claim 16,
wherein the minimum distance between the dummy gate structures and the gate structures is two times or more the first distance, and
wherein the dummy gate structures extend below the level of the top surface of the substrate and below a level of a top surface of the area isolation layer.

18. The semiconductor device according to claim 16, wherein:
the gate structures are spaced apart from one another by a second distance in the second horizontal direction; and
the first distance is equal to the second distance.

19. A semiconductor device comprising:
a substrate including a cell area and an interface area surrounding the cell area, the substrate including a device isolation layer defining an active region in the cell area and including an area isolation layer in the interface area;
a gate structure extending in the cell area in a first horizontal direction, the gate structure being buried in the substrate and intersecting the active region;
a bit line structure intersecting the gate structure and extending in a second horizontal direction intersecting the first horizontal direction;
a bit line material layer on the area isolation layer and being spaced apart from the bit line structure in the first horizontal direction;
edge spacers in the interface area, the edge spacers contacting side surfaces of the bit line structure and the bit line material layer;
a direct contact under the bit line structure in the cell area, the direct contact contacting the active region;
a buried contact at a side surface of the gate structure, the buried contact contacting the active region; and
dummy gate structures extending in the interface area in the first horizontal direction and being spaced apart from one another in the second horizontal direction,
wherein the dummy gate structures are buried in the area isolation layer and are spaced apart from the gate structure in the second horizontal direction.

20. The semiconductor device according to claim 19,
wherein the dummy gate structures are arranged in columns parallel to the second horizontal direction and rows parallel to the first horizontal direction, and
wherein the interface area is free of any contact that contacts the substrate.
